(19) United States
(12) Patent Application Publication
(10) Pub. No.: US 2018/0283966 A1
(43) Pub. Date: Oct. 4, 2018

(54) SENSOR DEVICE, FORCE DETECTION DEVICE, AND ROBOT

(71) Applicant: Seiko Epson Corporation, Tokyo (JP)

(72) Inventors: Akira MATSUZAWA, Shiojiri (JP); Hiroki KAWAI, Matsumoto (JP)

(21) Appl. No.: 15/940,024

(22) Filed: Mar. 29, 2018

(30) Foreign Application Priority Data
Mar. 31, 2017 (JP) 2017-071717

(51) Int. Cl. G01L 5/00; H01L 41/083; H01L 41/113; H01L 41/047; H01L 41/313; B25J 13/08; G01L 1/16

(52) U.S. Cl. CPC G01L 5/0061; H01L 41/083; H01L 41/1132; H01L 41/053; H01L 41/313; B25J 13/085; G01L 1/16; H01L 41/0477

(57) ABSTRACT

A sensor device includes a stacked body including a first piezoelectric element, a second piezoelectric element, and a macromolecule polymer film located between the first piezoelectric element and the second piezoelectric element.

### BACKGROUND

### 1. Technical Field

The present invention relates to a sensor device, a force detection device, and a robot.

### 2. Related Art

In the past, in an industrial robot having an end effector and a robot arm, there is used a force detection device for detecting force applied to the end effector. As an example of such a force detection device there is known, for example, a device having a plurality of piezoelectric elements, and using the piezoelectric effect of the piezoelectric elements.

In, for example, International Patent Publication No. WO 2013/146984 (Document 1), there is described a structure of a laminated piezoelectric element provided with a stacked body having a plurality of piezoelectric plates stacked on one another with internal electrodes sandwiched therebetween. The stacked body provided to the laminated piezoelectric element is manufactured by forming a conductive layer formed of silver-palladium alloy on each of an upper surface and lower surface of a plate-like piezoelectric body formed of ceramics, and then stacking a piezoelectric body provided with a conductive layer.

Here, since the piezoelectric body and the two internal electrodes each formed of the conductive layer are different in thermal expansion coefficient from each other, when external force is applied, the piezoelectric body and the internal electrodes are different in behavior from each other. Further, in the piezoelectric body provided to the laminated piezoelectric element according to Document 1, since there is adopted the configuration in which the piezoelectric bodies each provided with the conductive layer are directly connected to each other, there occurs a transmission loss of the external force due to the difference in thermal expansion coefficient between the piezoelectric body and the internal electrode, and therefore, there is a problem that the detection accuracy of the external force deteriorates.

### SUMMARY

An advantage of some aspects of the invention is to solve at least a part of the problems described above, and the invention can be implemented as the following application examples or aspects.

A sensor device according to an application example includes a stacked body including a first piezoelectric element, a second piezoelectric element, and a macromolecule polymer film located between the first piezoelectric element and the second piezoelectric element.

According to such a sensor device, since the macromolecule polymer film is disposed between the first piezoelectric element and the second piezoelectric element, it is possible to reduce the transmission loss of the external force between the first piezoelectric element and the second piezoelectric element. Therefore, it is possible to reduce the degradation of the detection accuracy of the external force.

In the sensor device according to the application example, it is preferable that the macromolecule polymer film includes polysiloxane.

According to the application example with this configuration, since the macromolecule polymer film including polysiloxane is small in thermal expansion coefficient, and is hard to be modified, it is possible to further reduce the transmission loss of the external force between the first piezoelectric element and the second piezoelectric element. Therefore, it is possible to reduce the degradation of the detection accuracy of the external force.

In the sensor device according to the application example, it is preferable that the first piezoelectric element and the second piezoelectric element each have a piezoelectric layer adapted to generate a charge due to a piezoelectric effect, and an electrode provided to the piezoelectric layer and adapted to output a signal corresponding to the charge, and the macromolecule polymer film is disposed between the electrode provided to the first piezoelectric element and the electrode provided to the second piezoelectric element.

According to the application example with this configuration, it is possible to reduce the occurrence of the transmission loss of the external force between the electrode provided to the first piezoelectric element and the electrode provided to the second piezoelectric element, and thus, it is possible to reduce the degradation of the detection accuracy of the external force.

In the sensor device according to the application example, it is preferable that there is further included a plurality of side surface electrodes disposed on a side surface of the stacked body, and at least a part of a material constituting the side surface electrodes is the same as at least a part of a material constituting the electrode.

According to the application example with this configuration, it is possible to reduce the connection failure between the side surface electrodes and the electrode.

In the sensor device according to the application example, it is preferable that the plurality of side surface electrodes includes a first layer including nickel, and a second layer including gold.

According to the application example with this configuration, it is possible to reduce the occurrence of the connection failure between the structure and the side surface electrodes, and at the same time, enhance the durability of the side surface electrodes. Further, such side surface electrodes can be used for, for example, taking out the signal output from the structure and then outputting the signal to the outside.

In the sensor device according to the application example, it is preferable that the piezoelectric layer includes quartz crystal.

According to the application example with this configuration, it is possible to realize the force detection device having excellent characteristics such as high sensitivity, wide dynamic range, and high rigidity.

In the sensor device according to the application example, it is preferable that defining thickness of the piezoelectric layer as T1, and thickness of the macromolecule polymer film as T2, 2.0≤T1/T2≤10000 is fulfilled.

According to the application example with this configuration, it is possible to more effectively reduce the degradation of the detection accuracy of the external force.

In the sensor device according to the application example, it is preferable that there is further included a package adapted to house the stacked body, and the package includes a base having a recess in which the stacked body is disposed, a lid disposed so as to close the opening of the recess, and a seal adapted to bond the base and the lid to each other.

According to the application example with this configuration, it is possible to protect the piezoelectric elements from the outside, and the noise due to the external influence can be reduced.

In the sensor device according to the application example, it is preferable that the seal includes Kovar.

According to the application example with this configuration, since Kovar is relatively small in thermal expansion coefficient, the thermal deformation of the seal can be reduced, and thus, it is possible to reduce the bonding failure between the base and the lid due to the thermal deformation.

In the sensor device according to the application example, it is preferable that the base includes a sensor plate, and a side wall bonded to the sensor plate so as to form the recess together with the sensor plate, and Young's modulus of the sensor plate is lower than Young's modulus of the side wall.

According to the application example with this configuration, it is possible to appropriately transmit the external force to the piezoelectric element, and at the same time, reduce the possibility of occurrence of the bonding failure between the sensor plate and the side wall due to the external force.

A force detection device according to an application example includes a first plate, a second plate, and the sensor device according to any one of the application examples described above disposed between the first plate and the second plate.

According to such a force detection device, it is possible to more accurately detect the external force.

A robot according to an application example includes a pedestal, and an arm connected to the pedestal, and the force detection device according to the application example described above attached to the arm.

According to such a robot, it is possible to more accurately perform operations.

### BRIEF DESCRIPTION OF THE DRAWINGS

The invention will be described with reference to the accompanying drawings, wherein like numbers reference like elements.

FIG. 1 is a perspective view showing a robot according to a first embodiment of the invention.

FIG. 2 is a diagram showing an end effector of a robot arm.

FIG. 3 is a top-side perspective view of a force detection device.

FIG. 4 is a bottom-side perspective view of the force detection device shown in FIG. 3.

FIG. 5 is a side cross-sectional view of the force detection device shown in FIG. 3.

FIG. 6 is a plan view showing the inside of the force detection device shown in FIG. 3.

FIG. 7 is a bottom-side perspective view of the force detection device shown in FIG. 3 in the state of removing a connection member.

FIG. 8 is a cross-sectional view showing the connection between the force detection device and an attachment member.

FIG. 9 is a cross-sectional view of a sensor device.

FIG. 10 is a plan view showing the sensor device mounted on an analog circuit board.

FIG. 11 is a diagram showing the force detection element.

FIG. 12 is a plan view showing terminals disposed on a package provided to the sensor device.

FIG. 13 is a plan view showing a back side of the package.

FIG. 14 is a diagram showing the connection between the analog circuit board and the sensor device.

FIG. 15 is a diagram showing another example of the connection between the analog circuit board and the sensor device.

FIG. 16 is a diagram showing another example of the connection between the analog circuit board and the sensor device.

FIG. 17 is a flowchart of a method of manufacturing a connection section provided to the force detection element.

FIG. 18 is a diagram for explaining a coating process.

FIG. 19 is a schematic diagram showing a part of a surface of the connection section in the coating process in an enlarged manner.

FIG. 20 is a diagram for explaining an energy application process.

FIG. 21 is a schematic diagram showing a part of the surface of the connection section in the energy application process in an enlarged manner.

FIG. 22 is a diagram for explaining a bonding process.

FIG. 23 is a diagram for explaining a pressurizing process.

FIG. 24 is a plan view showing terminals disposed on a package provided to a sensor device in a second embodiment of the invention.

FIG. 25 is a plan view showing a back side of the package shown in FIG. 24.

FIG. 26 is a diagram showing the connection between the analog circuit board and the sensor device.

FIG. 27 is a cross-sectional view showing the connection between a force detection device and an attachment member in a third embodiment of the invention.

FIG. 28 is a perspective view showing a robot according to a fourth embodiment of the invention.

### DESCRIPTION OF EXEMPLARY EMBODIMENTS

Some preferred embodiments of a sensor device, a force detection device, and a robot will hereinafter be described in detail based on the accompanying drawings. It should be noted that some parts of the drawings are displayed in an arbitrarily expanded or contracted manner or with omission so that parts to be explained are made recognizable. Further, in the specification, the word “connection” includes the case of being directly connected, and the case of being indirectly connected via an arbitrary member.

### 1. Robot

Firstly, an example of a robot according to the present application example will be described.

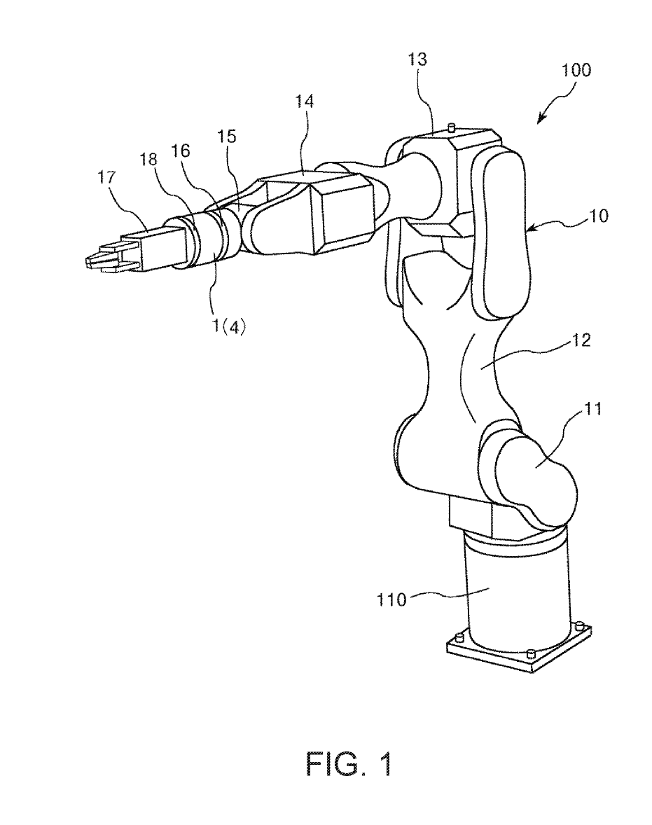

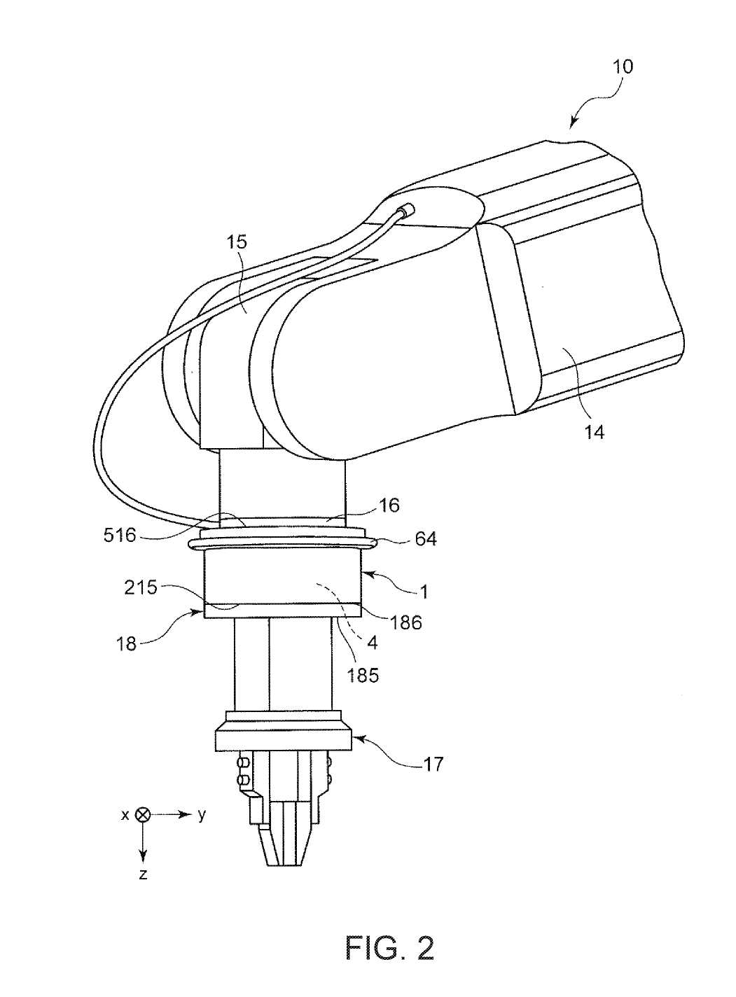

FIG. 1 is a perspective view showing the robot according to the first embodiment. FIG. 2 is a diagram showing an end effector of a robot arm. Further, in FIG. 2, there are shown an x axis, a y axis, and a z axis as three axes perpendicular to each other, and the tip side of the arrow indicating each of the axes is defined as “+,” and the base end side is defined as “−” for the sake of convenience of explanation. Further, a direction parallel to the x axis is referred to as an “x-axis direction,” a direction parallel to the y axis is referred to as a “y-axis direction,” and a direction parallel to the z axis is referred to as a “z-axis direction.” Further, the view from the z-axis direction is referred to as a “planar view.” Further, a pedestal 110 side in FIG. 1 is referred to as a “base end,” and an opposite side (an end effector 17 side) thereof is referred to as a “tip.”

The robot 100 shown in FIG. 1 is capable of performing operations such as feeding, removing, transmission, and assembling of an object such as precision mechanical equipment or a component constituting the precision mechanical equipment. The robot 100 is a so-called single arm six-axis vertical articulated robot.

The robot 100 has a pedestal 110, and a robot arm 10 rotatably connected to the pedestal 110. Further, to the robot arm 10, there is connected a force detection device 1, and to the force detection device 1, there is connected the end effector 17 (attachment target member) via an attachment member 18.

The pedestal 110 is apart to be fixed to, for example, the floor, the wall, the ceiling, or a movable carriage. It should be noted that it is sufficient that the robot arm 10 is connected to the pedestal 110, and it is also possible for the pedestal 110 itself to be made movable. The robot arm 10 has an arm 11 (a first arm), an arm 12 (a second arm), an arm 13 (a third arm), an arm 14 (a fourth arm), an arm 15 (a fifth arm), and an arm 16 (a sixth arm). These arms 11 through 16 are connected to one another in this order from the base end side toward the tip side. The arms 11 through 16 are made rotatable with respect to adjacent one of the arms 11 through 16 or the pedestal 110.

As shown in FIG. 2, the force detection device 1 is disposed between the arm 16 located in the tip part of the robot arm 10 and the end effector 17. The force detection device 1 is directly connected to the arm 16, and is connected to the end effector 17 via the attachment member 18.

The force detection device 1 detects force (including moment) applied to the end effector 17. It should be noted that the force detection device 1 will be described later in detail.

The end effector 17 is a device for performing some work on an object as a work object of the robot 100, and is formed of a hand having a function of gripping the object. It should be noted that it is sufficient to use an instrument corresponding to the work content of the robot 100 as the end effector 17, the end effector 17 is not limited to the hand, and can also be a screwing instrument for performing screwing.

The attachment member 18 is a member to be used for attaching the end effector 17 to the force detection device 1. It should be noted that the attachment member 18 will be described later in detail together with the force detection device 1.

Further, although not shown in the drawings, the robot 100 has a drive section provided with an electric motor or the like for rotating one of the arms with respect to the other (or the pedestal 110) of the arms. Further, although not shown in the drawings, the robot 100 has an angular sensor for detecting the rotational angle of a rotary shaft of the electric motor. Although not shown in the drawings, the drive section and the angular sensor are provided to, for example, each of the arms 11 through 16.

Such a robot 100 is provided with the pedestal 110, and the arm 16 (the robot arm 10) which is connected to the pedestal 110, and to which the force detection device 1 can be attached. According to such a robot 100, since it is possible to attach the force detection device 1 described later in detail to the robot arm 10 (the arm 16 in the present embodiment), by, for example, the force detection device 1 detecting the external force received by the end effector 17 connected to the force detection device 1, and performing feed-back control based on the detection result thereof, it is possible for the robot 100 to perform more precise work. Further, it is possible for the robot 100 to detect a contact and so on of the end effector 17 with an obstacle based on the detection result of the force detection device 1. Therefore, it is possible to easily perform an obstacle avoidance action, an object damage avoidance action, and so on, and thus, it is possible for the robot 100 to safely perform the work.

Further, the attachment member 18 is a separated member from the end effector 17 in the present embodiment, but can also be integrated with the end effector 17. Further, the configuration of the attachment member 18 is not limited to the configuration shown in the drawing.

Further, although the description is presented citing the case of using the end effector 17 as an example of the attachment target member as an example, the attachment target member is not limited to the end effector 17. For example, the attachment target member can also be the arm 15. The force detection device 1 can also be disposed between the arm 15 and the arm 16.

### 2. Force Detection Device

Then, an example of the force detection device according to the present application example will be described.

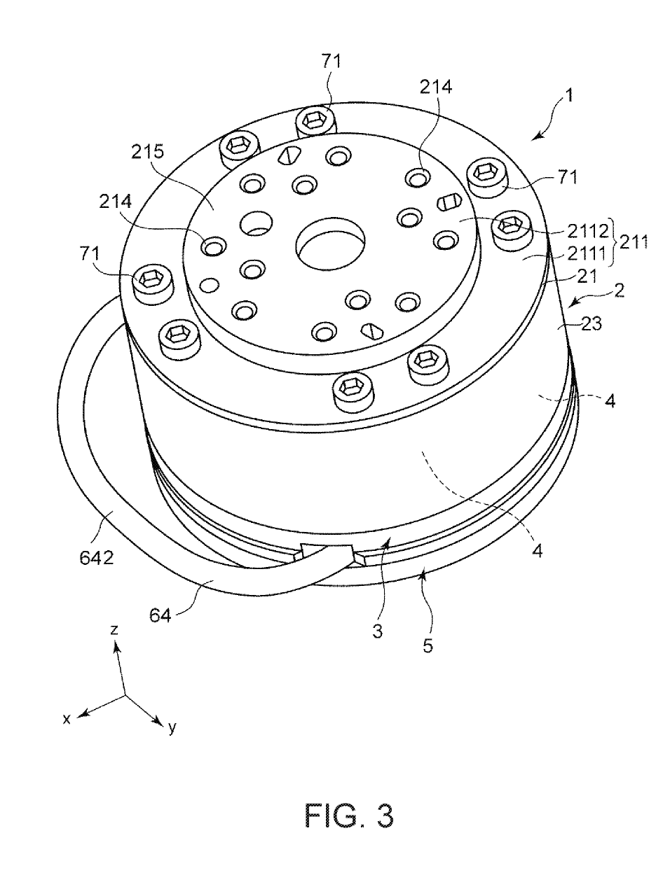

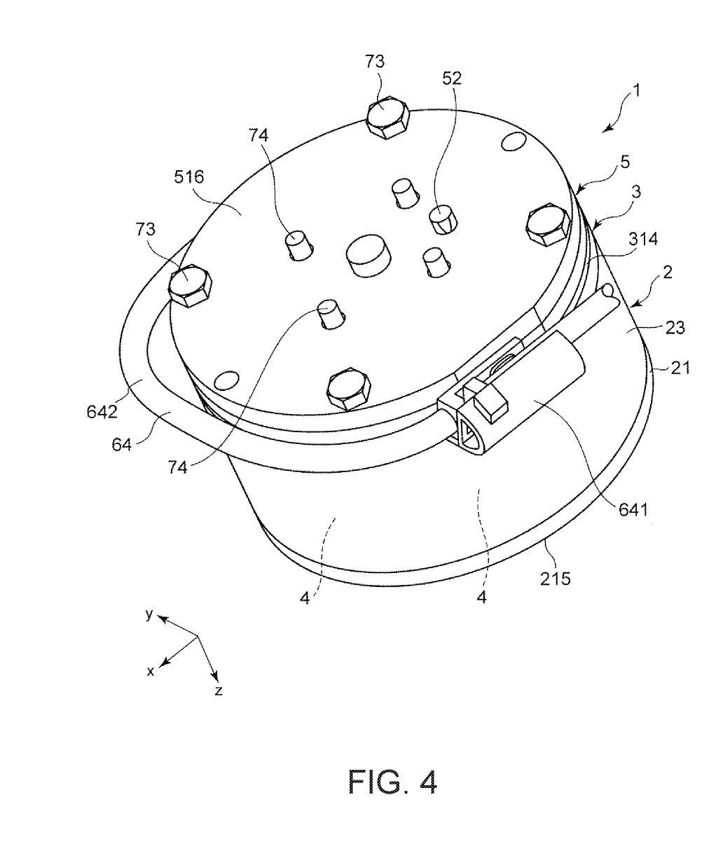

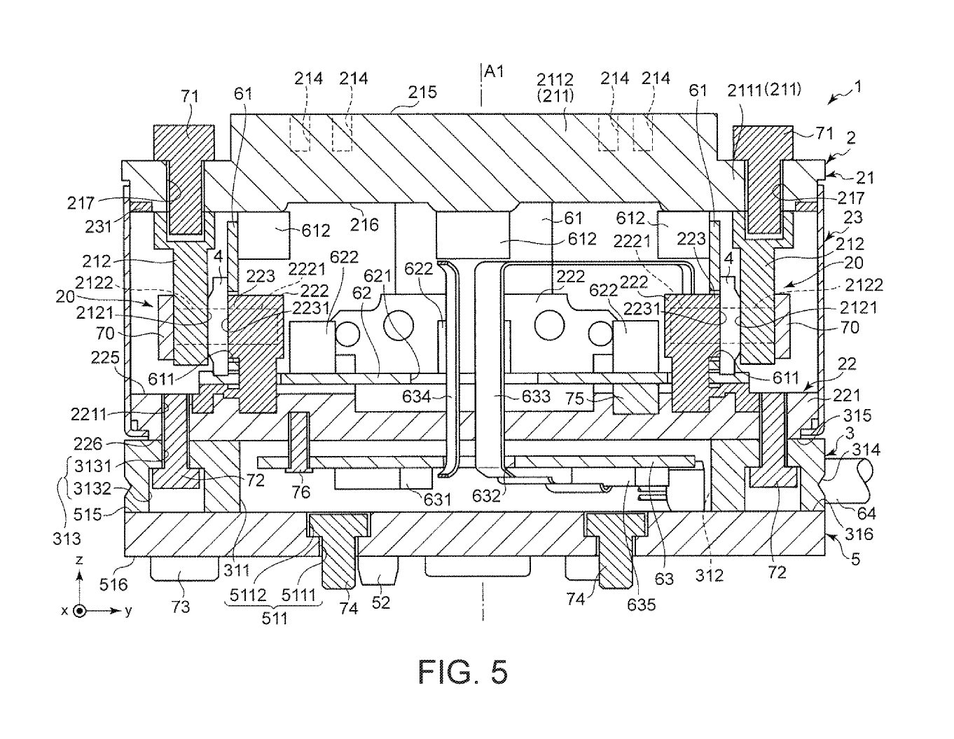

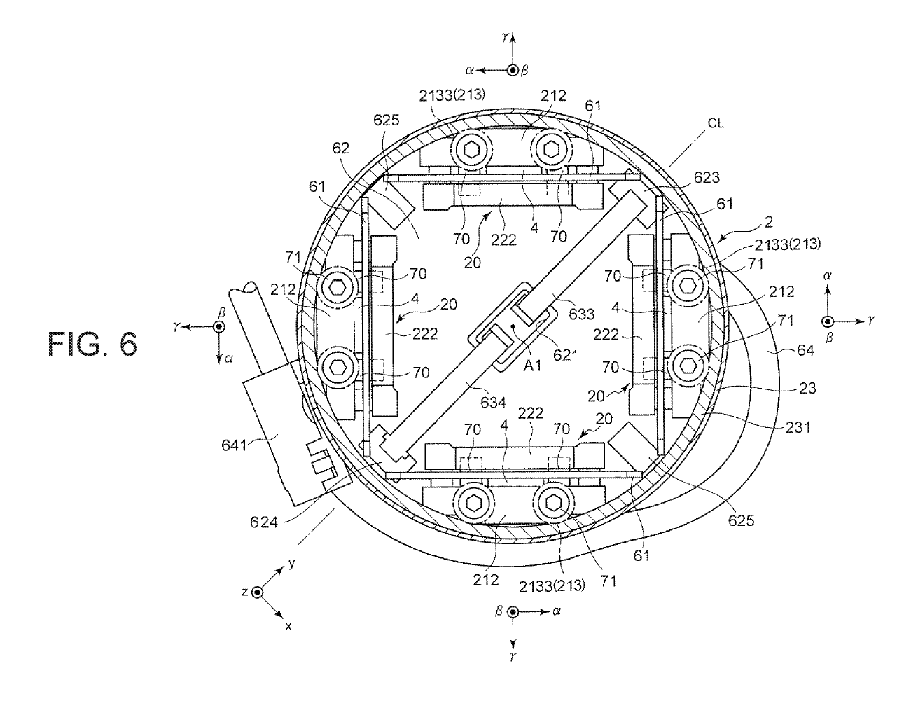

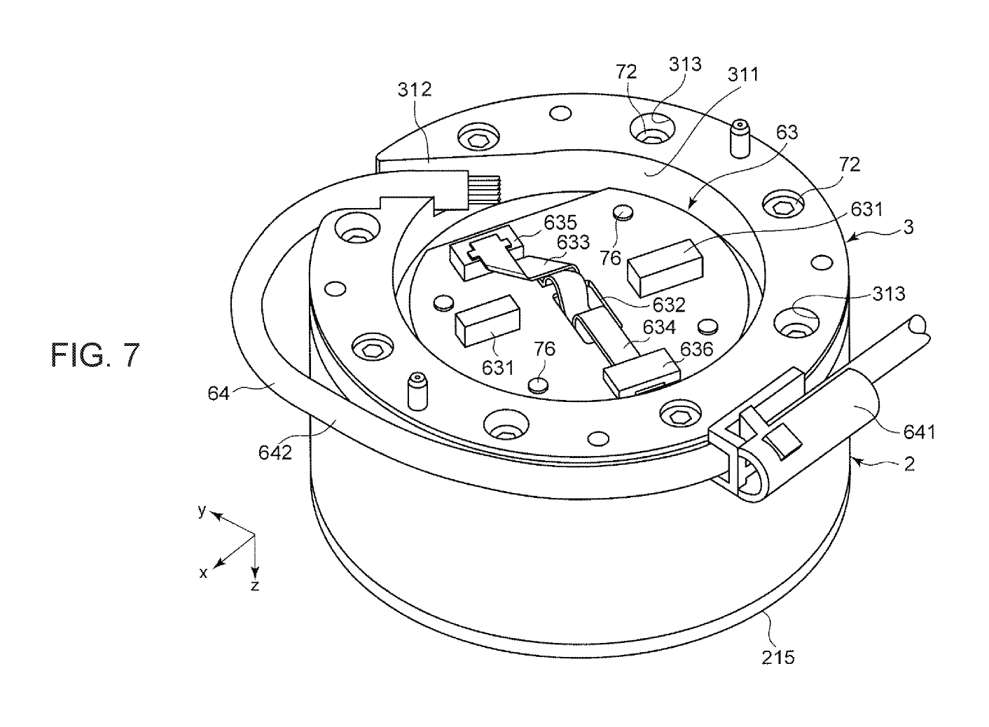

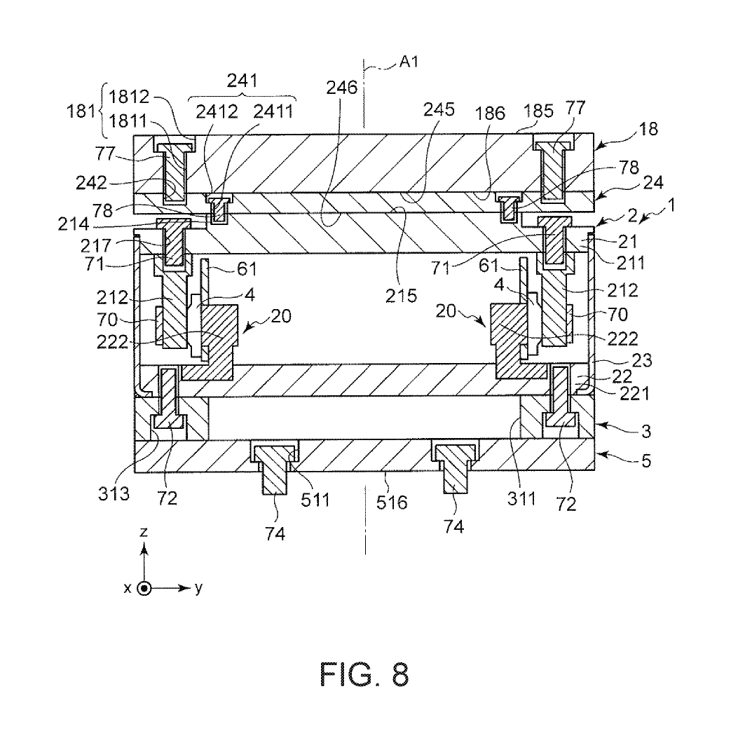

FIG. 3 is a top-side perspective view of the force detection device. FIG. 4 is a bottom-side perspective view of the force detection device shown in FIG. 3. FIG. 5 is a side cross-sectional view of the force detection device shown in FIG. 3. FIG. 6 is a plan view showing the inside of the force detection device shown in FIG. 3. FIG. 7 is a bottom-side perspective view of the force detection device shown in FIG. 3 in the state of removing a connection member. FIG. 8 is a cross-sectional view showing the connection between the force detection device and the attachment member. It should be noted that, hereinafter, the +z-axis direction side is also referred to as “upper side,” and the -z-axis direction side is also referred to as “lower side.”

The force detection device 1 shown in FIG. 3 and FIG. 3 is a six-axis kinesthetic sensor capable of detecting six-axis components of the external force applied to the force detection device 1. Here, the six-axis components are translational force (shearing force) components in the respective directions of the three axes (e.g., the x axis, the y axis, and the z axis shown in the drawings) perpendicular to each other, and rotational force (moment) components around the respective three axes.

As shown in FIG. 5, the force detection device 1 has a case 2, a plurality of sensor devices 4 housed in the case 2, a plurality of analog circuit boards 61 and a single digital circuit board 62, a board housing member 3 connected to the case 2, a relay board 63 housed in the board housing member 3, a connection member 5 connected to the board housing member 3, and an external wiring section 64 disposed on the outer periphery of the board housing member 3.

In the force detection device 1, the signals (the detection result) corresponding to the external force received by the respective sensor devices 4 are output, and the signals are processed by the analog circuit boards 61 and the digital circuit board 62. Thus, the six-axis components of the external force applied to the force detection device 1 are detected. Further, the signals processed by the digital circuit board 62 are output to the outside via the relay board 63 electrically connected to the digital circuit board 62 and the external wiring section 64 electrically connected to the relay board 63.

Hereinafter, the sections provided to the force detection device 1 will be described.

### Case

As shown in FIG. 5, the case 2 has a first case member 21, a second case member 22 disposed with a distance from the first case member 21, a sidewall section 23 (a third case member) disposed on the outer periphery of the first case member 21 and the second case member 22.

### First Case Member

The first case member 21 has a roughly tabular shape, and has a first plate 211 having an upper surface 215 and a lower surface 216, and a plurality of (four in the present embodiment) first fixation sections 212 (first wall, first pressurization sections) erected in the outer periphery of the lower surface 216 of the first plate 211.

### First Plate

The first plate 211 has an outer edge part 2111, and a central part 2112 thicker in thickness than the outer edge part 2111 and having a part protruding upward from the outer edge part 2111. Further, the first plate 211 is provided with a plurality of female screw holes 217 through which bolts 71 are inserted, and a plurality of female screw holes 214 (connection sections) located on the central axis A1 side of the female screw holes 217, and used for attaching a member 24 to be connected to the attachment member 18.

Here, as shown in FIG. 8, in the present embodiment, the attachment member 18 has a disk-like shape having an upper surface 185 and a lower surface 186, and in the outer periphery of the attachment member 18, there is disposed a plurality of through holes 181 penetrating in the thickness direction. To the upper surface 185, there is attached the end effector 17, and to the lower surface 186, there is connected (see FIG. 2 and FIG. 8) the force detection device 1 via the member 24. Each of the through holes 181 includes a hole 1811 through which a bolt 77 is inserted, and a hole 1812 which is communicated with the hole 1811, and in which a head of the bolt 77 is located. Further, the through hole 181 and the through hole 217 of the first plate 211 are disposed at positions corresponding to each other. In the present embodiment, the through hole 181 is located immediately above the through hole 217, and the through hole 217 and the hole 1811 overlap each other in a planar view.

Further, the member 24 provided to the case 2 has a tabular shape having an upper surface 245 and a lower surface 246. Further, the upper surface 245 is connected to the attachment member 18, and the lower surface 246 is connected to the first plate 211 . The member 24 has a plurality of through holes 241 and a plurality of female screw holes 242 located on the opposite side to the central axis A1 with respect to the plurality of through holes 241.

Each of the through holes 241 includes a hole 2411 through which a bolt 78 is inserted, and a hole 2412 which is communicated with the hole 2411, and in which a head of the bolt 78 is located. Further, the female screw hole 242 corresponds to the male thread of the bolt 77 used for connecting the attachment member 18 to the member 24. Further, the female screw holes 242 are disposed at positions respectively corresponding to the through holes 181 of the attachment member 18, and the bolts 77 are respectively inserted through the through holes 181 and the female screw holes 242.

It should be noted that it is sufficient for the attachment member 18 to be a member with which the force detection device 1 can be attached to the end effector 17 (the attachment target member), and the attachment member 18 is not limited to the member shown in the drawings.

### First Fixation Sections

As shown in FIG. 6, the plurality of first fixation sections 212 is arranged along the same circumference centered on the central axis A1 of the force detection device 1 at regular angular intervals (90°).

Further, as shown in FIG. 6, the through holes 217 described above and the first fixation section 212 corresponding to the through holes 217 overlap each other in the planar view. Further, as shown in FIG. 5, an inner wall surface 2121 (an inner end surface) of each of the first fixation sections 212 is a plane perpendicular to the first plate 211. Further, each of the first fixation sections 212 is provided with a plurality of female screw holes 2122 through which pressurization bolts 70 described later are respectively inserted.

Each of such first fixation sections 212 is connected to the first plate 211 and the sensor device 4, and has a function of transmitting the external force applied to the force detection device 1 to the sensor device 4.

The constituent material of such a first case member 21 is not particularly limited, but there can be cited, for example, metal materials such as aluminum and stainless steel, and ceramics. Further, the outer shape in the planar view of the first case member 21 is the circular shape as shown in FIG. 3, but is not limited thereto, and can also be, for example, a polygonal shape such as a quadrangular shape or a pentagonal shape, or an elliptical shape. Further, in the drawings, the first fixation sections 212 and the first plate 211 are formed as separated members, but can also be integrated with each other. Further, the first fixation sections 212 and the first plate 211 can be formed of the same material, or can also be formed of respective materials different from each other.

### Second Case Member

As shown in FIG. 5, the second case member 22 has a roughly tabular shape, and has a second plate 221 having an upper surface 225 and a lower surface 226, and a plurality of (four in the present embodiment) second fixation sections 222 (second wall, second pressurization sections) erected in the outer periphery of the upper surface 225 of the second plate 221.

### Second Plate

The second plate 221 is disposed so as to be opposed to the first plate 211. In the outer periphery of the second plate 221, there is formed a plurality of female screw holes 2211 corresponding respectively to the male threads of bolts 72 for connecting the board housing member 3 and the second plate 221 to each other.

### Second Fixation Sections

As shown in FIG. 6, the plurality of second fixation sections 222 is arranged along the same circumference centered on the central axis A1 of the force detection device 1 at regular angular intervals (90°). The second fixation sections 222 are disposed on the central axis A1 side with respect to the first fixation sections 212 of the first case member 21 described above, and are respectively opposed to the first fixation sections 212. Further, as shown in FIG. 5, on the first fixation section 212 side of each of the second fixation sections 222, there is provided a protruding part 223 protruding toward the first fixation section 212. A top surface 2231 of the protruding part 223 faces to the inner wall surface 2121 of the first fixation section 212 described above with a predetermined distance, namely a distance with which the sensor device 4 can be inserted. Further, the top surface 2231 and the inner wall surface 2121 are parallel to each other. Further, each of the second fixation sections 222 is provided with a plurality of female screw holes 2221 each of which the tip part of the pressurization bolt 70 described later screw together.

Each of such second fixation sections 222 is connected to the second plate 221 and the sensor device 4, and has a function of transmitting the external force applied to the force detection device 1 to the sensor device 4.

The constituent material of such a second case member 22 is not particularly limited, but there can be cited, for example, metal materials such as aluminum and stainless steel, and ceramics similarly to the first case member 21 described above. It should be noted that the constituent material of the second case member 22 can be the same as the constituent material of the first case member 21, or can also be different therefrom. Further, in the present embodiment, the outer shape in the planar view of the second case member 22 is the circular shape corresponding to the outer shape of the first case member 21, but is not limited thereto, and can also be, for example, a polygonal shape such as a quadrangular shape or a pentagonal shape, or an elliptical shape. Further, in the drawings, the second fixation sections 222 and the second plate 221 are formed as separated members, but can also be integrated with each other. Further, the second fixation sections 222 and the second plate 221 can be formed of the same material, or can also be formed of respective materials different from each other.

### Sidewall Section

As shown in FIG. 3 and FIG. 4, the sidewall section 23 (the third case member) has a cylindrical shape. As shown in FIG. 6, an upper end part of the sidewall section 23 is provided with a seal member 231 formed of, for example, an O-ring. Due to the seal member 231, the first plate 211 fitted to the upper end part of the sidewall section 23 (see FIG. 5). Further, similarly, due to a seal member not shown, the second plate 221 is fitted to the lower end part of the sidewall section 23.

Here, the Young's modulus (longitudinal elastic modulus) of the seal member 231 is lower than the Young's modulus of the sidewall section 23 and the first plate 211. The constituent material of the seal member 231 is not particularly limited, but it is possible to use, for example, a variety of types of resin materials such as polyester resin or polyurethane resin, and a variety of types of elastomer such as silicone rubber. It should be noted that the same applies to the seal member (not shown) for fitting the second plate 221 to the sidewall section 23. By providing such a seal member 231 and such a seal member (not shown) for fitting the second plate 221 to the sidewall section 23, it is possible to form an airtight internal space.

It should be noted that it is possible for the first plate 211 and the second plate 221 to be fixed to the sidewall section 23 with, for example, screwing, respectively.

The constituent material of such a sidewall section 23 is not particularly limited, but there can be cited, for example, metal materials such as aluminum and stainless steel, and ceramics similarly to the first case member 21 and the second case member 22 described above. It should be noted that the constituent material of the sidewall 23 can be the same as the constituent material of the first case member 21 and the second case member 22, or can also be different therefrom.

In the case 2 having such a configuration, there are housed the plurality of sensor devices 4, the plurality of analog circuit board 61 and the digital circuit board 62 described later in detail. Further, in the case 2, there is disposed a temperature sensor having a function of detecting the temperature inside the case 2 although not shown in the drawings.

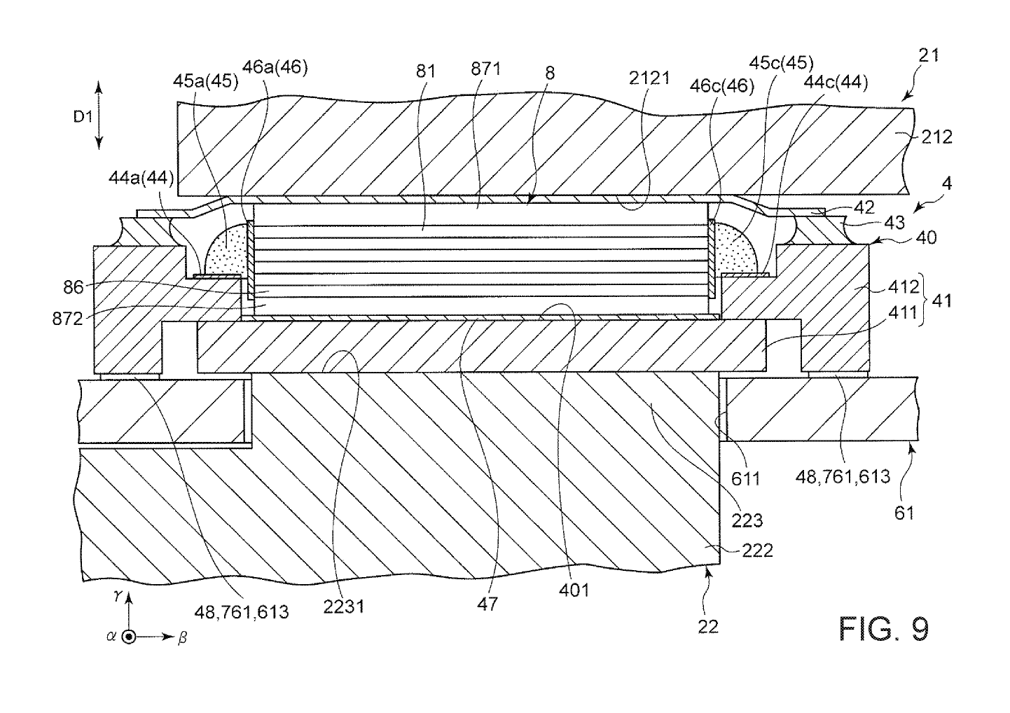

Further, between the first fixation sections 212 and the second fixation sections 222 described above, there are disposed the sensor devices 4 described later, respectively. Specifically, due to the plurality of pressurization bolts 70 (pressurization members) each inserted through the through hole 217 of the first fixation member 212 and the female screw hole 2221 of the corresponding second fixation section 222, each of the sensor devices 4 is held in a state of being sandwiched and pressurized by the first fixation section 212 and the second fixation section 222. In the present embodiment, as shown in FIG. 6, there are disposed two pressurization bolts 70 for each of the sensor devices 4 on both sides thereof. Further, by appropriately adjusting the fastening force of each of the pressurization bolts 70, it is possible to apply pressure (pressure in the stacking direction D1 shown in FIG. 9 described later) of a predetermined level as pressurization to the sensor devices 4.

The constituent material of each of such pressurization bolts 70 is not particularly limited, but there can be cited, for example, a variety of types of metal materials. It should be noted that the locations and the number of the pressurization bolts 70 are not limited to the locations and the number shown in the drawings. Further, the number of the pressurization bolts 70 can also be, for example, one, or three or more for each of the sensor devices 4. Further, it is also possible to fix the sensor device 4 using a fixation member other than the pressurization bolts 70, or to omit the fixation member such as the pressurization bolts 70 providing the sensor device 4 can be fixed with the first fixation section 212 and the second fixation section 222. Further, although in the present embodiment, the first fixation section 212 and the second fixation section 222 are disposed so as to sandwich the sensor device 4 along the stacking direction D1 shown in FIG. 9 described later, it is sufficient for each of the first fixation section 212 and the second fixation section 222 to have contact with the sensor device 4, and the arrangement of the first fixation section 212 and the second fixation section 222 is not limited to the arrangement shown in the drawings.

Here, the first fixation sections 212, the second fixation sections 222, and the pressurization bolts 70 described above constitute a “fixation section” for fixing the sensor devices 4 to the first plate 211 and the second plate 221. Further, in the present embodiment, the fixation section, the sensor devices 4, and the analog circuit boards 61 constitute a “structure 20.”

It should be noted that in the present specification, the “fixation section” described above denotes what is provided with at least the first fixation section 212 and the second fixation section 222. Further, in the present specification, the “structure” described above denotes what is provided with the sensor device 4 and the fixation section.

### Board Housing Member

As shown in FIG. 5, the board housing member 3 is disposed between the case 2 and the connection member 5, wherein an upper surface 315 of the board housing member 3 is connected to the second case member 22, and a lower surface 316 of the board housing member 3 is connected to the connection member 5 described later. The board housing member 3 has a cylindrical shape having a hole 311 penetrating in a central part. The board housing member 3 has a recessed part 312 communicated with the hole 311 and opens to the side surface and the lower surface 316, a plurality of through holes 313 disposed on the outer side of the hole 311, and a groove 314 formed on the side surface of the board housing member 3 (see FIG. 5 and FIG. 7).

As shown in FIG. 7, in the hole 311, there is housed the relay board 63 described later. The opening area of the hole 311 is not particularly limited providing the shape of the relay board 63 can be housed. Further, inside the recessed part 312, there is disposed one end part of the external wiring section 64 described later.

As shown in FIG. 5, in the outer periphery of the board housing member 3, there is formed the plurality of through holes 313 through which bolts 72 for connecting the board housing member 3 to the second plate 221 are respectively inserted. Each of the through holes 313 includes a hole 3131 through which the bolt 72 is inserted, and a hole 3132 which is communicated with the hole 3131, and in which a head of the bolt 72 is located.

As shown in FIG. 4 and FIG. 5, the groove 314 (a recessed part) is formed along the circumferential direction of the board housing member 3. Around the groove 314, there is wound the external wiring section 64 described later. It should be noted that the groove 314 can be formed throughout the entire circumference of the board housing member 3, or can also be formed in a part thereof.

The constituent material of such a board housing member 3 is not particularly limited, but there can be cited, for example, metal materials such as aluminum and stainless steel, and ceramics similarly to the first case member 21 described above. It should be noted that the constituent material of the board housing member 3 can be the same as the constituent material of the first case member 21 and so on, or can also be different therefrom. Further, in the present embodiment, the outer shape in the planar view of the board housing member 3 is the circular shape corresponding to the outer shape of the second case member 22, but is not limited thereto, and can also be, for example, a polygonal shape such as a quadrangular shape or a pentagonal shape, or an elliptical shape.

### Connection Members

As shown in FIG. 5, the connection member 5 has a tabular shape having an upper surface 515 and a lower surface 516, wherein the upper surface 515 is connected to the board housing member 3. The upper surface 515 is connected to the board housing member 3 to thereby block the opening on the lower surface 316 side of the recessed part 312 provided to the board housing member 3 described above, and thus, a hole through which a part of the external wiring section 64 is inserted is formed. Further, the lower surface 516 of the connection member 5 is connected to the arm 16 (see FIG. 2).

The connection member 5 has a plurality of female screw holes (not shown) which is disposed in the outer periphery of the connection member 5, and through which bolts 73 for connecting the connection member 5 to the board housing member 3 are respectively inserted, a plurality of through holes 511 located on the central axis A1 side of the female screw holes, and a positioning section 52 disposed on the lower surface 516. Each of the through holes 511 includes a hole 5111 through which a bolt 74 for connecting the connection member 5 to the arm 16 is inserted, and a hole 5112 which is communicated with the hole 5111, and in which a head of the bolt 74 is located. The positioning section 52 is used for performing positioning of the force detection device 1 with respect to the arm 16, for example.

The constituent material of such a connection member 5 is not particularly limited, but there can be cited, for example, metal materials such as aluminum and stainless steel, and ceramics similarly to the board housing member 3 described above. It should be noted that the constituent material of the connection member 5 can be the same as the constituent material of the board housing member 3 and so on, or can also be different therefrom. Further, in the present embodiment, the outer shape in the planar view of the connection member 5 is the circular shape corresponding to the outer shape of the board housing member 3, but is not limited thereto, and can also be, for example, a polygonal shape such as a quadrangular shape or a pentagonal shape, or an elliptical shape. Further, as shown in FIG. 5, side surfaces of the connection member 5, the board housing member 3, and the case 2 are located on roughly the same circumferential surface.

### Analog Circuit Boards

As shown in FIG. 6, inside the case 2, there is disposed a plurality of (four in the present embodiment) analog circuit boards 61. In the present embodiment, the analog circuit boards 61 are disposed for the respective sensor devices 4 in a one-to-one manner, and one of the sensor devices 4 and corresponding one of the analog circuit boards 61 are electrically connected to each other. Further, the analog circuit boards 61 are electrically connected to the digital circuit board 62.

As shown in FIG. 5, each of the analog circuit boards 61 has a hole 611 through which the protruding part 223 of the second fixation section 222 is inserted, holes (not shown) through which the pressurization bolts 70 are respectively inserted, and a connector 612 used for electrically connecting the analog circuit board 61 and the digital circuit board 62 to each other. Further, each of the analog circuit boards 61 is located between the first fixation section 212 and the second fixation section 222, and is disposed on the central axis A1 side with respect to the sensor device 4 in the state of being inserted through the protruding part 223.

Such an analog circuit board 61 is provided with a charge amplifier (a conversion output circuit) for converting the charges Q (Qα, Qβ, Qγ) output from the sensor devices 4 described later respectively into voltages V (Vα, Vβ, Vγ) although not shown in the drawings. The charge amplifier can be configured including, for example, an operational amplifier, a capacitor, and a switching element.

### Digital Circuit Board

As shown in FIG. 5, inside the case 2, there is disposed the digital circuit board 62. In the present embodiment, the digital circuit board 62 is fixed to an upper part of the second case member 22 with a fixation member 75 provided to the second case member 22. The digital circuit board 62 is electrically connected to each of the analog circuit boards 61 and the relay board 63 described later.

The digital circuit board 62 has a hole 621 formed in the central part thereof, connectors 622 electrically connected to the connectors 612 of the respective analog circuit boards 61 with wiring cables or the like not shown, connectors 623, 624 electrically connected to the relay board described later, and a plurality of connectors 625 electrically connected to the temperature sensors not shown (see FIG. 5 and FIG. 6).

Although not shown in the drawings, such a digital circuit board 62 is provided with an external force detection circuit for detecting (calculating) the external force based on the voltages V from the analog circuit boards 61. The external force detection circuit calculates a translational force component Fx in the x-axis direction, a translational force component Fy in the y-axis direction, a translational force component Fz in the z-axis direction, a rotational force component Mx around the x axis, a rotational force component My around the y axis, and a rotational force component Mz around the z axis. The external force detection circuit can be configured including, for example, an AD converter, and an arithmetic circuit such as a CPU connected to the AD converter.

### Relay Board

As shown in FIG. 5, the relay board 63 disposed inside the hole 311 of the board housing member 3 is fixed to the second case member 22 with bolts 76. Due to the relay board 63, it is possible to provide a channel for performing feedback control from the robot controller (not shown) for controlling drive of the robot arm 10 of the robot 100 and force detection information, and an input channel of a correction parameter.

As shown in FIG. 7, the relay board 63 has an electronic component 631 for performing a variety of processes, a hole 632 disposed in a central part, and connectors 635, 636. Further, the relay board 63 is electrically connected to the digital circuit board 62 with wiring cables 633, 634 each formed of, for example, a flexible board (see FIG. 5 and FIG. 6).

Specifically, the wiring cable 633 is connected to the connector 635, and is inserted through the hole 632 of the relay board 63 and the hole 621 of the digital circuit board 62, then extends toward the first plate 211, and is then laid around the outer periphery in the case 2, and is then connected to the connector 623 of the digital circuit board 62 (see FIG. 5 through FIG. 7). The wiring cable 633 is used for inputting the correction parameters to the sensor devices 4. Further, the wiring cable 634 is connected to the connector 636, and is inserted through the hole 632 of the relay board 63 and the hole 621 of the digital circuit board 62, then extends toward the first plate 211, and is then laid around the outer periphery in the case 2, and is then connected to the connector 624 of the digital circuit board 62. The wiring cable 634 is used for performing arithmetic processing on the output from each of the sensor devices 4.

### External Wiring Section

As shown in FIG. 7, the external wiring section 64 is formed of, for example, a plurality of wiring cables and a tube or the like for bundling the wiring cables. As described above, an end of the external wiring section 64 is disposed in the recessed part 312 of the board housing member 3, and is electrically connected to the relay board 63. Further, the other end of the external wiring section 64 is connected to the robot arm 10 described above (see FIG. 2).

Further, a part of the external wiring section 64 is supported by a support section 641 disposed on the side surface of the board housing member 3. Thus, there is restricted the translation of apart 642 of the external wiring section 64 located between the support section 641 and the recessed part 312 of the board housing member 3. Thus, the corresponding motion of the part 642 of the external wiring section 64 is restricted even if other parts of the external wiring section 64 than the part 642 moves in accordance with the drive of the robot arm 10 (see FIG. 2 and FIG. 7). Therefore, it is possible to arrange that the electrical connection between the external wiring section 64 and the relay board 63 is not affected even if the robot arm 10 is driven.

### Sensor Device

As shown in FIG. 6, the four sensor devices 4 are arranged so as to be symmetric about a line segment CL passing through the central axis A1 and parallel to the y axis in the planar view (when viewed from a direction along the central axis A1).

The sensor devices 4 will hereinafter be described in detail.

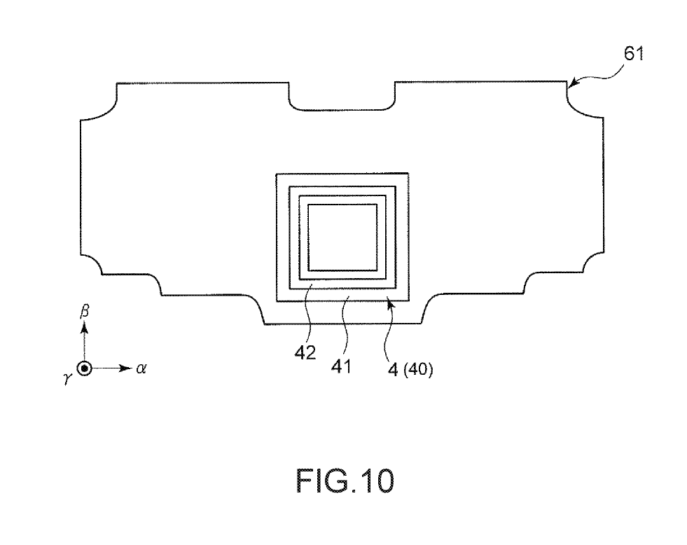

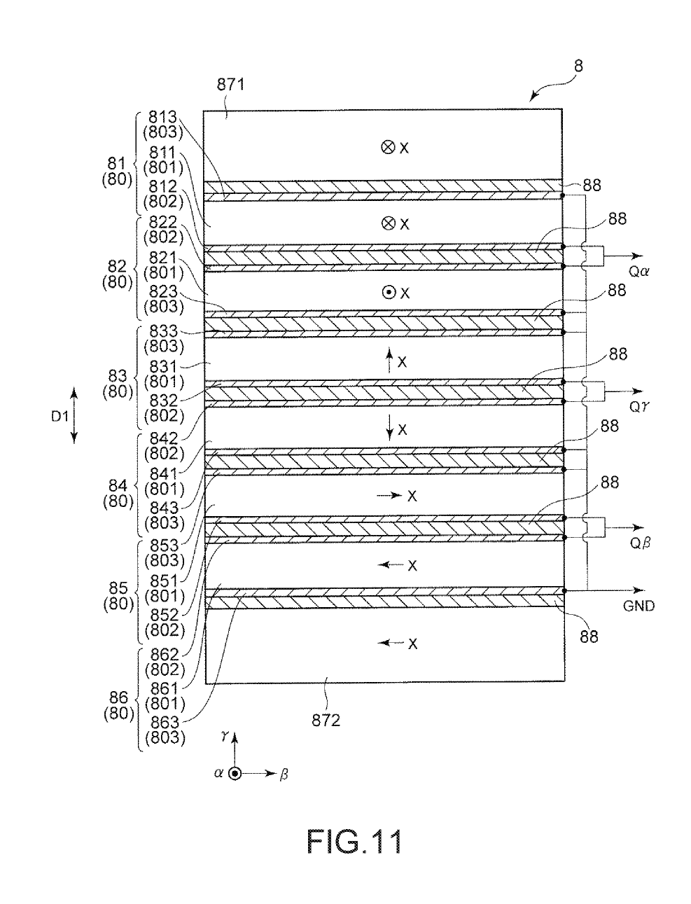

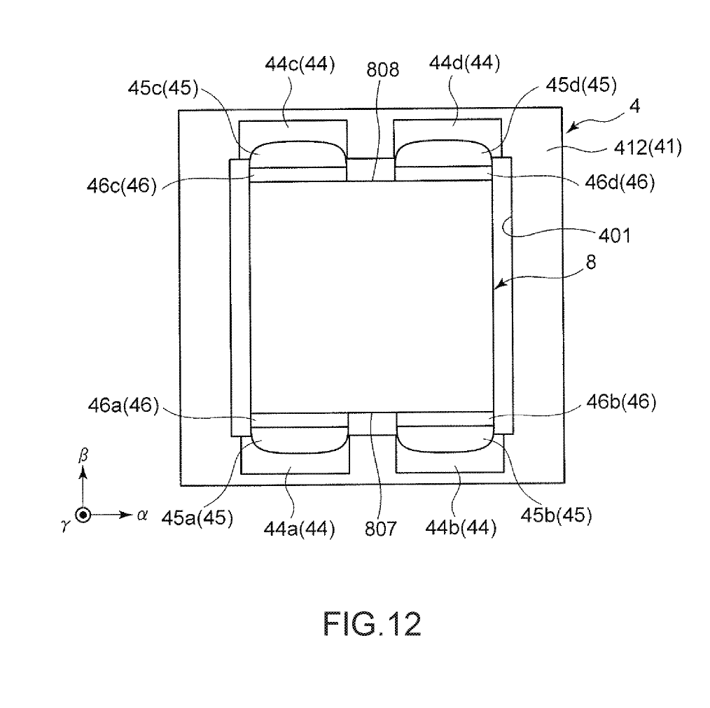

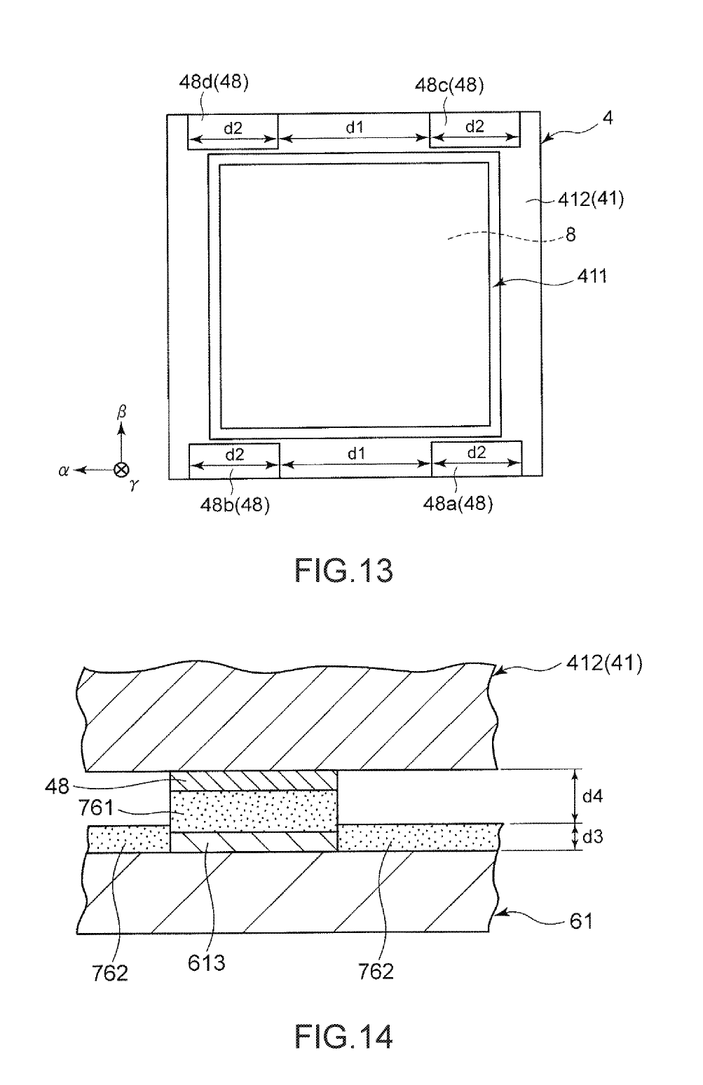

FIG. 9 is a cross-sectional view of the sensor device. FIG. 10 is a plan view showing the sensor device mounted on the analog circuit board. FIG. 11 is a diagram showing the force detection element. FIG. 12 is a plan view showing terminals disposed on a package provided to the sensor device. FIG. 13 is a plan view showing the back side of the package. FIG. 14 is a diagram showing the connection between the analog circuit board and the sensor device. Further, in FIG. 6 described above and FIG. 9 through FIG. 13, there are shown an α axis, a β axis, and a γ axis as three axes perpendicular to each other, and the tip side of the arrow indicating each of the axes is defined as “+,” and the base end side is defined as “−.” Further, a direction parallel to the α axis is referred to as an “α-axis direction,” a direction parallel to the β axis is referred to as a “β-axis direction,” and a direction parallel to the γ axis is referred to as a “γ-axis direction.” It should be noted that, hereinafter, the +γ-axis direction side is also referred to as “upper side,” and the -γ-axis direction side is also referred to as “lower side.”

The four sensor devices 4 have substantially the same configurations except the difference in arrangement in the case 2. Each of the sensor devices 4 has a function of detecting the external force (specifically, shearing force, compression or tensile force) applied along the three axes, namely the a axis, the β axis, and the γ axis, perpendicular to each other. In the present embodiment, as shown in FIG. 6, the sensor devices 4 are arranged so that the + side of the γ axis is directed to the opposite side to the central axis A1 in a planar view, and the β-axis direction and the z-axis direction become parallel to each other.

As shown in FIG. 9, each of the sensor devices 4 has a force detection element 8, a package 40 for housing the force detection element 8, a plurality of internal terminals 44 provided to the package 40, a plurality of side surface electrodes 46 provided to the force detection element 8, a plurality of conductive connection sections 45 electrically connecting the side surface electrodes 46 and the internal terminals 44 to each other, a bonding member 47 bonding the force detection element 8 to the package 40, and a plurality of external terminals 48 disposed on the outer surface of the package 40. Further, as shown in FIG. 10, the sensor device 4 is mounted on the analog circuit board 61 described above.

### Force Detection Element

The force detection element 8 (the stacked body) shown in FIG. 11 has a function of outputting the charge Qα corresponding to the component in the α-axis direction of the external force applied to the force detection element 8, the charge Qβ corresponding to the component in the β-axis direction of the external force applied to the force detection element 8, and the charge Qγ corresponding to the component in the γ-axis direction of the external force applied to the force detection element 8.

The force detection element 8 has two piezoelectric elements 81, 82 for outputting the charge Qα in accordance with the external force (shearing force) parallel to the α axis, two piezoelectric elements 83, 84 for outputting the charge Qγ in accordance with the external force (compression/tensile force) parallel to the γ axis, two piezoelectric elements 85, 86 for outputting the charge Qβ in accordance with the external force (shearing force) parallel to the β axis, two support substrates 871, 872, and a plurality of connection sections 88. Here, the support substrate 871, the connection section 88, the piezoelectric element 81, the connection section 88, the piezoelectric element 82, the connection section 88, the piezoelectric element 83, the connection section 88, the piezoelectric element 84, the connection section 88, the piezoelectric element 85, the connection section 88, the piezoelectric element 86, the connection section 88, and the support substrate 872 are stacked on one another in this order. Further, as shown in FIG. 9, the support substrate 871 is located on the first fixation section 212 side, and the support substrate 872 is located on the second fixation section 222 side. It should be noted that it is also possible for the support substrate 871 to be located on the second fixation section 222 side, and for the support substrate 872 to be located on the first fixation section 212 side. It should be noted that, hereinafter, the piezoelectric elements 81, 82, 83, 84, 85, 86 are each referred to as a “piezoelectric element 80” in the case in which the piezoelectric elements 81, 82, 83, 84, 85, 86 are not distinguished from each other.

### Piezoelectric Element

As shown in FIG. 11, the piezoelectric element 81 has a ground electrode layer 813 electrically connected to a reference potential (e.g., the ground potential GND), a piezoelectric layer 811, and an output electrode layer 812, and these layers are stacked on one another in this order. Similarly, the piezoelectric element 82 has an output electrode layer 822, a piezoelectric layer 821, and a ground electrode layer 823, and these layers are stacked on one another in this order. Further, the piezoelectric elements 81, 82 are disposed so that the output electrode layer 812 and the output electrode layer 822 are connected to each other via the connection section 88. Further, the ground electrode layer 813 of the piezoelectric element 81 and the support substrate 871 are connected to each other via the connection section 88.

Similarly, the piezoelectric element 83 has a ground electrode layer 833, a piezoelectric layer 831, and an output electrode layer 832, and these layers are stacked on one another in this order. Further, the piezoelectric element 84 has an output electrode layer 842, a piezoelectric layer 841, and a ground electrode layer 843, and these layers are stacked on one another in this order. Further, the piezoelectric elements 83, 84 are disposed so that the output electrode layer 832 and the output electrode layer 842 are connected to each other via the connection section 88. Further, the ground electrode layer 833 of the piezoelectric element 83 and the ground electrode layer 823 of the piezoelectric element 82 described above are connected to each other via the connection section 88.

Similarly, the piezoelectric element 85 has a ground electrode layer 853, a piezoelectric layer 851, and an output electrode layer 852, and these layers are stacked on one another in this order. Further, the piezoelectric element 86 has an output electrode layer 862, a piezoelectric layer 861, and a ground electrode layer 863, and these layers are stacked on one another in this order. Further, the piezoelectric elements 85, 86 are disposed so that the output electrode layer 852 and the output electrode layer 862 are connected to each other via the connection section 88. Further, the ground electrode layer 853 of the piezoelectric element 85 and the ground electrode layer 843 of the piezoelectric element 84 described above are connected to each other via the connection section 88. Further, the ground electrode layer 863 of the piezoelectric element 86 and the support substrate 872 are connected to each other via the connection section 88.

It should be noted that, hereinafter, the piezoelectric layers 811, 821, 831, 841, 851, 861 are each referred to as a “piezoelectric layer 801” in the case in which the piezoelectric layers 811, 821, 831, 841, 851, 861 are not distinguished from each other. Further, the output electrode layers 812, 822, 832, 842, 852, 862 are each referred to as an “output electrode layer 802” in the case in which the output electrode layers 812, 822, 832, 842, 852, 862 are not distinguished from each other. Further, the ground electrode layers 813, 823, 833, 843, 853, 863 are each referred to as a “ground electrode layer 803” in the case in which the ground electrode layers 813, 823, 833, 843, 853, 863 are not distinguished from each other.

As described above, in the present embodiment, each of the piezoelectric elements 80 has the piezoelectric layer 801 for generating the charge Q due to the piezoelectric effect, and the output electrode layer 802 (electrode) provided to the piezoelectric layer 801, and for outputting a signal (a voltage V) corresponding to the charge. Further, the piezoelectric elements 80 each have the ground electrode layer 803. By using the piezoelectric elements 80 each having such a configuration, the external force received by the force detection device 1 can be detected with high sensitivity.

Further, each of the piezoelectric layers 801 includes quartz crystal (is formed of quartz crystal). Thus, it is possible to realize the force detection device 1 having excellent characteristics such as high sensitivity, wide dynamic range, and high rigidity.

As shown in FIG. 11, the direction of the X axis as the crystal axis of the quartz crystal constituting the piezoelectric layer 801 is different between the piezoelectric layers 801. Specifically, the X axis of the quartz crystal constituting the piezoelectric layer 811 is directed to the back side of the sheet of FIG. 11. The X axis of the quartz crystal constituting the piezoelectric layer 821 is directed to the front side of the sheet of FIG. 11. The X axis of the quartz crystal constituting the piezoelectric layer 831 is directed upward in FIG. 11. The X axis of the quartz crystal constituting the piezoelectric layer 841 is directed downward in FIG. 11. The X axis of the quartz crystal constituting the piezoelectric layer 851 is directed rightward in FIG. 11. The X axis of the quartz crystal constituting the piezoelectric layer 861 is directed leftward in FIG. 11. Such piezoelectric layers 811, 821, 851, 861 are each formed of a Y-cut quartz crystal plate, and are different in X axis direction as much as 90° from each other. Further, the piezoelectric layers 831, 841 are each formed of an X-cut quartz crystal plate, and are different in X axis direction as much as 180° from each other.

It should be noted that the piezoelectric layers 801 are each formed of the quartz crystal in the present embodiment, but can also be provided with a configuration of using a piezoelectric material other than the quartz crystal. As the piezoelectric material other than the quartz crystal, there can be cited, for example, topaz (aluminum silicate), barium titanate, lead titanate, lead zirconium titanate (PZT (Pb(Zr,Ti)O₃)), lithium niobate, and lithium tantalate.

The thickness of the piezoelectric layer 801 is not particularly limited, but is in a range of, for example, 0.1 through 3000 μm.

Further, the output electrode layer 812 outputs the charge Qα generated due to the piezoelectric effect of the piezoelectric layer 811. Similarly, the output electrode layer 822 outputs the charge Qα generated due to the piezoelectric effect of the piezoelectric layer 821. Further, the output electrode layer 832 outputs the charge Qγ generated due to the piezoelectric effect of the piezoelectric layer 831. Similarly, the output electrode layer 842 outputs the charge Qγ generated due to the piezoelectric effect of the piezoelectric layer 841. Further, the output electrode layer 852 outputs the charge Qβ generated due to the piezoelectric effect of the piezoelectric layer 851. Similarly, the output electrode layer 862 outputs the charge Qβ generated due to the piezoelectric effect of the piezoelectric layer 861.

The materials constituting the output electrode layers 802 and the ground electrode layers 803 are not particularly limited providing the materials can function as electrodes, but there can be cited, for example, nickel, gold, titanium, aluminum, copper, iron, chromium, and alloys including these materials, and it is possible to use either one of these materials, or two or more of these materials in combination (e.g., stacked on one another). Among these materials, in particular, nickel (Ni) is preferably used. Thus, in the case in which the piezoelectric layer 801 is formed of quartz crystal as in the present embodiment, a difference in thermal expansion coefficient between the piezoelectric layer 801, and the output electrode layer 802 and the ground electrode layer 803 can be made small. Specifically, the difference between the both layers can be made no higher than 10%. Therefore, even if the piezoelectric elements 80 are thermally deformed, it is possible to reduce generation of the stress caused by the thermal deformation to thereby reduce output of an unwanted signal caused by the stress.

Further, all of the output electrode layers 802 and the ground electrode layers 803 can be formed of respective materials different from each other, but are preferably formed of the same material. Thus, it is possible to prevent or reduce the error in the output which can be caused by the difference in material.

The thickness of the output electrode layer 802 and the thickness of the ground electrode layer 803 are not particularly limited, but are each in a range of, for example, 0.05 through 100 μm.

### Support Substrates

The support substrates 871, 872 (dummy substrates) support the piezoelectric elements 80.

The thickness of each of the support substrates 871, 872 is thicker than the thickness of each of the piezoelectric layers 801. Thus, it is possible to stably connect the force detection element 8 to the package 40 described later. Further, by providing the support substrate 872, it is possible to separate a bottom member 411 provided to the package 40 described later and the piezoelectric element 86 from each other, and by providing the support substrate 871, it is possible to separate a lid member 42 (a lid) provided to the package 40 described later and the piezoelectric element 81 from each other (see FIG. 9).

The thickness of each of the support substrates 871, 872 is not particularly limited, but is in a range of, for example, 0.1 through 5000 μm.

Further, the support substrates 871, 872 are each formed of quartz crystal. Further, the support substrate 871 is formed of a quartz crystal plate (a Y-cut quartz crystal plate) having substantially the same configuration as that of the piezoelectric layer 811 provided to the adjacent piezoelectric element 81, and the direction of the X axis is also the same as in the piezoelectric layer 811. Further, the support substrate 872 is formed of a quartz crystal plate (a Y-cut quartz crystal plate) having substantially the same configuration as that of the piezoelectric layer 861 provided to the adjacent piezoelectric element 86, and the direction of the X axis is also the same as in the piezoelectric layer 861. Here, since the quartz crystal has an anisotropic nature, the thermal expansion coefficient is different between the X axis, the Y axis, and the Z axis as the crystal axes thereof. Therefore, in order to suppress the stress due to the thermal expansion, it is preferable for the support substrates 871, 872 to have substantially the same configuration and arrangement (direction) as those of the adjacent piezoelectric layers 811, 861, respectively, as shown in the drawing.

It should be noted that the support substrates 871, 872 each can also be formed of a material other than the quartz crystal similarly to each of the piezoelectric layers 801.

### Connection Sections

The connection sections 88 each connect the piezoelectric elements 80 to each other, and are each formed of an insulating material, and each have a function of blocking the conduction between the piezoelectric elements 80.

The connection sections 88 are each formed of a macromolecular polymer film including a polymeric material. As the polymeric material, those relatively small in thermal expansion coefficient (polymer with low thermal expansion coefficient) are preferable, and there can be used, for example, polyimide, polysiloxane, acrylonitrile-styrene, polycarbonate, polymethylmethacrylate, polyphenylene oxide, phenol resin, urea resin, and melamine resin. Among these materials, it is preferable for the connection sections 88, namely the macromolecular polymer film, to include polysiloxane. Thus, the macromolecular polymer film including polysiloxane is small in thermal expansion coefficient and is hard to be deformed compared to an adhesive or the like. Further, such a macromolecular polymer film is superior in stability over time. Therefore, it is possible to further reduce the loss of detection of the external force between the piezoelectric elements 80, and thus, it is possible for the force detection element 8 to detect the external force with higher accuracy.

It should be noted that polysiloxane denotes a compound having a main backbone (main chain) formed of siloxane bond. Polysiloxane can be provided with a branch structure having a structure shaped like a branch projecting from a part of the main chain, or with a cyclic structure in which the main chain forms a cyclic shape, or with a linear structure in which the ends of the main chain are not connected to each other. By providing such a main backbone with the siloxane bond, the connection sections 88 formed of the macromolecule polymer film become strong films hard to be deformed. Further, as a typical example of polysiloxane, there can be cited, for example, silicone or a modified body thereof.

Here, when the external force is applied, a deformation (strain) is caused in the piezoelectric layer 801 due to the piezoelectric effect, and the piezoelectric layer 801 and the output electrode layer 802 are different from each other in behavior when the external force is applied due to the difference in constituent material and so on. Therefore, if the output electrode layers 802 are directly connected to each other, the stress caused between the output electrode layers 802 is output together with the deformation of the piezoelectric layer 801 generated due to the piezoelectric effect, and thus, the detection error occurs. In contrast, in the present embodiment, since the connection section 88 formed of the macromolecule polymer film is disposed between the output electrode layers 802, it is possible to reduce or remove generation of such a detection error as described above. Further, if the output electrode layers 802 are connected to each other with an adhesive or the like, the adhesive has a relatively soft configuration, and therefore, absorbs or attenuates the deformation of the piezoelectric layer 801. Therefore, the detection sensitivity degrades. In contrast, in the present embodiment, since the connection section 88 formed of the macromolecule polymer film is disposed, it is possible to reduce or prevent such a degradation of the detection sensitivity as described above.

Further, it is possible for the macromolecule polymer film constituting the connection sections 88 to include a material other than polysiloxane, but the content of the polysiloxane included in the macromolecule polymer film is preferably no lower than 70 wt. %, and more preferably no lower than 90 wt. %. By using the connection sections 88 formed of such a macromolecule polymer film, the advantage of including polysiloxane can sufficiently be applied, and it is possible to further reduce the detection loss of the external force between the piezoelectric elements 80. Further, in the case in which the macromolecule polymer film includes a substance other than polysiloxane, it is preferable to include the polymer with a low thermal expansion coefficient described above. In this case, it can be cited to include the substance as a blend or a copolymer with polysiloxane.

Further, the thermal expansion coefficient of the macromolecule polymer film constituting the connection sections 88 is not particularly limited, but is preferably no lower than 1.0 (×10-⁵/K) and no higher than 7.0 (×10-⁵/K), and is more preferably no lower than 2.0 (×10-⁵/K) and no higher than 5.5 (×10-⁵/K). Thus, the advantage described above can remarkably be exerted.

The thickness of each of the connection sections 88 is not particularly limited, but is preferably in a range of, for example, about 0.1 through 10000 nm, and is more preferably in a range of 1.0 through 1000 nm, and is further more preferably in a range of 50 through 500 nm. Thus, it is possible to effectively reduce the detection loss of the external force between the piezoelectric elements 80.

Further, defining the thickness of the piezoelectric layer 801 as T1, and the thickness of the connection section formed of the macromolecule polymer (in particular, polysiloxane) film as T2, 2.0≤T1/T2≤10000 is preferably fulfilled, 5.0≤T1/T2≤5000 is more preferably fulfilled, and 10.0≤T1/T2≤1000 is further more preferably fulfilled. Thus, it is possible to more effectively reduce the detection accuracy of the external force while achieving miniaturization of the force detection element 8. Further, it is particularly preferable that the thickness T1 of each of the piezoelectric layers 801 provided to the force detection element 8, and the thickness T2 of each of the connection sections 88 satisfy the relationships described above. Thus, the advantage described above can remarkably be exerted. It should be noted that it is not required for all of the piezoelectric layers 801 and all of the connection sections 88 to fulfill the relationships described above.

Further, the composition, the thickness, the shape, and so on of the macromolecule polymer film constituting the connection section 88 are the same in the present embodiment, but can also be different between the connection sections 88. Further, it is possible for at least one of the connection sections 88 to be a stacked body of two or more layers, and in such a case, it is sufficient for at least one layer of the stacked body to be formed of the macromolecule polymer film such as polysiloxane described above.

The force detection element 8 is hereinabove described. As described above, the force detection element 8 is formed of the plurality of piezoelectric elements 80 stacked on one another. Specifically, defining the three axes perpendicular to each other as the α axis, the β axis, and the γ axis, the force detection element 8 has the piezoelectric elements 83, 84 (first piezoelectric elements) respectively provided with the piezoelectric layers 831, 841 each formed of the X-cut quartz crystal plate, and for outputting the charge Qγ in accordance with the external force along the γ-axis direction. Further, the force detection element 8 has the piezoelectric elements 81, 82 (second piezoelectric elements) respectively provided with the piezoelectric layers 811, 821 each formed of the Y-cut quartz crystal plate, and for outputting the charge Qα in accordance with the external force in the α-axis direction. Further, the force detection element 8 has the piezoelectric elements 85, 86 (third piezoelectric elements) provided with the piezoelectric layers 851, 861 each formed of the Y-cut quartz crystal plate, disposed so that the piezoelectric elements 83, 84 are sandwiched between the piezoelectric elements 81, 82 and the piezoelectric elements 85, 86, and for outputting the charge Qβ in accordance with the external force in the β-axis direction. Thus, due to the anisotropic nature of the piezoelectric effect derived from the crystal orientation of the quartz crystal, it is possible to resolve and then detect the external force thus applied. Specifically, it is possible to detect the translational force components of the three axes perpendicular to each other independently of each other. As described above, by providing the plurality of (two or more) piezoelectric elements 80 to the force detection element 8, it is possible for the force detection element 8 to achieve the multiaxial detection. Further, although it is possible for the force detection element 8 to detect the translational force components of the three axes perpendicular to each other independently of each other by being provided with at least one first piezoelectric element, at least one second piezoelectric element, and at least one third piezoelectric element, it is possible for the force detection element 8 to improve the output sensitivity by being provided with the two first piezoelectric elements, the two second piezoelectric elements, and the two third piezoelectric elements as in the present embodiment. As described above, by being provided with the plurality of (two or more) first through third piezoelectric elements, it is possible for the force detection element 8 to achieve the high-sensitivity force detection device 1.

It should be noted that the stacking sequence of each of the piezoelectric elements 80 is not limited to one shown in the drawing. Further, the number of the piezoelectric elements constituting the force detection element 8 is not limited to the number described above. For example, the number of the piezoelectric elements can be 1 through 5, or can also be 7 or more. Further, the overall shape of the force detection element 8 is a rectangular solid shape in the present embodiment, but is not limited thereto, and can also be, for example, a columnar shape, or another polyhedral shape.

### Package

As shown in FIG. 9, the package 40 is a member for housing the force detection element 8. The package 40 has a base part 41 having a recessed part 401 (a recess) in which the force detection element 8 is disposed, and the lid member 42 bonded to the base part 41 via a seal member 43 (a seal) so as to close the opening of the recessed part 401.

### Base Part

The base part 41 (a base) has a bottom member 411 having a tabular shape, and a sidewall member 412 bonded (fixed) to the bottom member 411. The bottom member 411 and the sidewall member 412 form the recessed part 401.

### Bottom Member

The bottom member 411 (a sensor plate) has a rectangular tabular shape, and has contact with the protruding part 223 of the second fixation section 222. In the present embodiment, the bottom member 411 incorporates the top surface 2231 of the protruding part 223 viewed from the γ-axis direction. Further, the bottom member 411 is connected to the force detection element 8 via the bonding member 47 formed of, for example, an adhesive having an insulating property. It should be noted that the bonding member 47 can also include, for example, a filler, water, a solvent, a plasticizer, a hardener, and an antistatic agent in addition to the adhesive.

As described above, the bottom member 411 connected directly to the protruding part 223 of the second fixation section 222, and connected to the force detection element 8 via the bonding member 47 has a function of transmitting the external force applied to the force detection device 1 to the force detection element 8.

As a specific constituent material of such a bottom member 411, there can be cited a variety of types of metal materials such as stainless steel, Kovar, copper, iron, carbon steel, and titanium, and among these materials, in particular, Kovar is preferable. Thus, the bottom member 411 is provided with relatively high rigidity, and at the same time, appropriately deforms elastically when stress is applied thereto. Therefore, it is possible for the bottom member 411 to appropriately transmit the external force applied to the second case member 22 to the force detection element 8, and at the same time reduce the possibility that the bottom member 411 is damaged due to the external force, and the possibility that the bonding failure occurs between the bottom member 411 and the sidewall member 412. Further, Kovar is preferable from the viewpoint that Kovar is superior in molding workability.

### Sidewall Member

The sidewall member 412 (a side wall) has a rectangular cylindrical shape, and has a protruding part protruding inner side of the recessed part 401. The protruding part is formed throughout the entire circumference of the sidewall member 412, and is bonded on the bottom member 411.

It is preferable for a constituent material of such a sidewall member 412 to be a material having an insulating property, and to consist primarily of a variety of types of ceramics such as oxide-based ceramics such as alumina or zirconia, carbide-based ceramics such as silicon carbide, or nitride-based ceramics such as silicon nitride. The ceramics has appropriate rigidity, and at the same time, is superior in insulating property. Therefore, damage due to the deformation of the package 40 is hard to occur, and it is possible to more surely protect the force detection element 8 housed inside. Further, it is possible to more surely prevent short circuit between the internal terminals 44 provided to the sidewall member 412 described later, and short circuit between the external terminals 48 provided to the sidewall member 412. Further, it is also possible to further improve the working accuracy of the sidewall member 412.

As described above, the base part 41 has the bottom member 411 (the first member), and the sidewall member 412 (the second member) bonded to the bottom member 411 to form the recessed part 401 together with the bottom member 411. Further, it is preferable for the Young's modulus of the bottom member 411 to be lower than the Young's modulus of the sidewall member 412. Thus, it is possible to appropriately transmit the external force to the force detection element 8, and at the same time, to reduce the possibility that the bottom member 411 is damaged, and the possibility that the bonding failure between the bottom member 411 and the sidewall member 412 occurs due to the external force and the pressurization with the pressurization bolts 70.

Further, a difference between the Young's modulus (longitudinal elastic modulus) of the bottom member 411 and the Young's modulus of the lid member 42 is preferably no higher than 10%, more preferably no higher than 5%, and further more preferably no higher than 3%. Thus, the advantage described above can more remarkably be exerted.

Specifically, the Young's modulus of the bottom member 411 is preferably no lower than 50 GPa and no higher than 300 GPa, more preferably no lower than 100 GPa and no higher than 250 GPa, and further more preferably no lower than 120 GPa and no higher than 200 GPa. The Young's modulus of the sidewall member 412 is preferably no lower than 200 GPa and no higher than 500 GPa, more preferably no lower than 250 GPa and no higher than 480 GPa, and further more preferably no lower than 300 GPa and no higher than 450 GPa. The Young's modulus of the lid member 42 is preferably no lower than 50 GPa and no higher than 300 GPa, more preferably no lower than 100 GPa and no higher than 250 GPa, and further more preferably no lower than 120 GPa and no higher than 200 GPa.

### Seal Member

The seal member 43 shown in FIG. 9 is formed of, for example, a ring-like sealing, and is disposed on the entire circumference of the upper surface of the base part 41.

As a constituent material of such a seal member 43, any material can be used providing the material has a function of bonding the lid member 42 to the base part 41, but it is possible to form the seal member 43 from, for example, gold, silver, titanium, aluminum, copper, iron, Kovar, or alloys including any of these materials. Among these materials, Kovar is preferably included in the seal member 43. Thus, since Kovar is relatively small in thermal expansion coefficient, the thermal deformation of the seal member 43 can be reduced, and thus, it is possible to reduce the possibility of occurrence of the bonding failure between the base part 41 and the lid member 42 due to the thermal deformation.

Further, it is preferable to use a cladding material for the seal member 43, and specifically, it is particularly preferable to use the cladding material having a configuration of sandwiching the layer including Kovar with two layers each including nickel. Thus, it is possible to further reduce the possibility of occurrence of the bonding failure between the sidewall member 412 and the lid member 42 due to the seal member 43. Further, the durability of the seal member 43 can be enhanced.

Further, it is preferable to use the same material for the seal member 43 as the material constituting the lid member 42 described later. Thus, it is possible to make the lid member 42 and the seal member 43 the same or similar in thermal expansion coefficient, and thus, it is possible to reduce the possibility of occurrence of the boding failure between the seal member 43 and the lid member 42 caused by the difference in thermal deformation between these members.

### Lid Member

The lid member 42 (a lid) has a plate-like shape, and is bonded to the base part 41 via the seal member 43 so as to close the opening of the recessed part 401. The lid member 42 is disposed so as to have contact with the first fixation section 212 and the force detection element 8, and has a function of transmitting the external force applied to the force detection device 1 to the force detection element 8. Further, in the present embodiment, the edge part side of the lid member 42 is bent toward the base part 41, and is disposed so as to cover the force detection element 8.

The constituent material of such a lid member 42 is not particularly limited, but similarly to the bottom member 411 described above, there can be cited a variety of types of metal materials such as stainless steel, Kovar, copper, iron, carbon steel, and titanium, and among these materials, in particular, Kovar is preferable. Thus, similarly to the bottom member 411, it is possible to more accurately transmit the external force to the force detection element 8, and at the same time, it is possible to further reduce the damage caused by the external force.

Further, the constituent material of the lid member 42 and the constituent material of the bottom member 411 can also be different from each other, but preferably include the same material. Thus, it is possible to make the both members the same or similar in thermal expansion coefficient, the Young's modulus, and so on, and thus, it is possible to more accurately transmit the external force applied to the force detection device 1 to the force detection element 8.

The package 40 is hereinabove described. As described above, the sensor device 4 has the package 40 for housing the force detection element 8 (a stacked body). The package 40 has a base part 41 having a recessed part 401 in which the force detection element 8 (the stacked body) is disposed, and the lid member 42 disposed so as to close the opening of the recessed part 401, and the seal member 43 for bonding the base part 41 and the lid member 42 to each other. Thus, it is possible to protect the piezoelectric elements 80 from the outside, and the noise due to the external influence can be reduced. Therefore, the detection accuracy of the force detection device 1 can effectively be enhanced.

Further, the outer shape of the package 40 forms a rectangular shape viewed from the γ-axis direction as shown in FIG. 10 in the present embodiment, but is not limited thereto, and can also be, for example, another polygonal shape such as a pentagonal shape, a circular shape, or an elliptical shape.

### Side Surface Electrodes

As shown in FIG. 9 and FIG. 12, the plurality of (four in the present embodiment) side surface electrodes 46 is disposed on the side surface of the force detection element 8. It should be noted that in the following description, out of the four side surface electrodes 46, the side surface electrode 46 located on the lower left side in FIG. 12 is referred to as “side surface electrode 46a,” the side surface electrode 46 located on the lower right side in FIG. 12 is referred to as “side surface electrode 46b,” the side surface electrode 46 located on the upper left side in FIG. 12 is referred to as “side surface electrode 46c,” and the side surface electrode 46 located on the upper right side in FIG. 12 is referred to as “side surface electrode 46d.” Further, the side surface electrodes 46a, 46b, 46c, 46d are each referred to as “side surface electrode 46” in the case in which the side surface electrodes 46a, 46b, 46c, 46d are not distinguished from each other.

The side surface electrode 46d is electrically connected to the output electrode layers 812, 822 of the force detection element 8 (see FIG. 11 and FIG. 12). Similarly, the side surface electrode 46c is electrically connected to the output electrode layers 832, 842 of the force detection element 8. Further, the side surface electrode 46a is electrically connected to the output electrode layers 852, 862 of the force detection element 8. Further, the side surface electrode 46b is electrically connected to the ground electrode layers 803 of the force detection element 8.

Further, the side surface electrodes 46a, 46b are disposed on the same side surface 807 of the force detection element 8 so as to be separated from each other. Further, the side surface electrodes 46c, 46d are disposed on the same side surface 808 opposed to the side surface on which the side surface electrodes 46a, 46b are disposed so as to be separated from each other.

It should be noted that the arrangement relationship between the side surface electrodes 46a, 46b, 46c, 46d is not limited to the illustration, and the side surface electrodes 46a, 46b, 46c, 46d can also be disposed on, for example, the same surface of the force detection element 8, or respective surfaces different from each other. Further, the positions, the sizes, the shapes, and so on of the respective side surface electrodes 46 are not limited to those shown in the drawings. Further, it is also possible for all of the side surface electrodes 46 to be the same in size and shape, or to be different in size and shape from each other.

It is preferable to use the same material for such side surface electrodes 46 as the material constituting the output electrode layers 802 (the electrodes) . Specifically, the sensor device 4 has the plurality of side surface electrodes 46 disposed on the side surfaces 807, 808 of the force detection element 8 (the stacked body). Further, it is preferable for at least a part of the material constituting the side surface electrodes 46 to be the same as at least a part of the material constituting the output electrode layers 802 (the electrodes). Thus, it is possible to enhance the adhesiveness between the side surface electrodes 46 and the output electrode layers 802, and therefore, it is possible to reduce the connection failure between the side surface electrodes 46 and the output electrode layers 802. Further, in the present embodiment, at least a part of the material constituting the side surface electrodes 46 is the same as at least a part of the material constituting the ground electrode layers 803. Therefore, it is possible to reduce the connection failure between the side surface electrodes 46 and the ground electrode layers 803.

Specifically, as the constituent material of the side surface electrodes 46, there can be cited, for example, nickel, gold, titanium, aluminum, copper, and iron, and it is possible to use one of these materials alone, or two or more of these materials in combination. Among these materials, in particular, each of the side surface electrodes 46 is preferably formed of metal layers obtained by stacking a second layer formed of either of gold, platinum, and iridium on a first layer formed of either of nickel, chromium, and titanium, and is more preferably formed of metal layers obtained by stacking a second layer formed of gold on a first layer formed of nickel. In other words, it is more preferable for the side surface electrode 46 to include a first layer including nickel, and a second layer including gold. Further, it is preferable for the first layer to have contact with the force detection element 8.

In the case in which each of the piezoelectric layers 801 is made of quartz crystal, the first layer including either of nickel, chromium, and titanium has the thermal expansion coefficient approximate to the thermal expansion coefficient of each of the piezoelectric layers 801. Therefore, it is possible to reduce the difference in thermal deformation between the first layer and each of the piezoelectric layers 801. Therefore, it is possible to enhance the adhesiveness between each of the piezoelectric layers 801 and each of the side surface electrodes 46, and therefore, it is possible to reduce the bonding failure between each of the piezoelectric layers 801 and each of the side surface electrodes 46. Further, by using the second layer formed of either of gold, platinum, and iridium, it is possible to prevent or suppress the oxidation of the side surface electrodes 46, and it is possible to enhance the durability of the side surface electrodes 46. In particular, by the side surface electrodes 46 including the first layer including nickel and the second layer including gold, the advantages described above can particularly remarkably be exerted.

It should be noted that the side surface electrodes 46 can also be formed of respective materials different from each other, but are preferably formed of the same material. Thus, it is possible to prevent or reduce the error in the output which can be caused by the difference in material.

Further, each of the side surface electrodes 46 can be formed using, for example, a sputtering method or a plating method. Thus, each of the side surface electrodes 46 can easily be formed.

### Internal Terminals

As shown in FIG. 9 and FIG. 12, the plurality of (four in the present embodiment) internal terminals 44 is located inside the recessed part 401, and is disposed on the lid member 42-side surface of the protruding part provided to the sidewall member 412 described above. It should be noted that in the following description, out of the four internal terminals 44, the internal terminal 44 located on the lower left side in FIG. 12 is referred to as “internal terminal 44a,” the internal terminal 44 located on the lower right side in FIG. 12 is referred to as “internal terminal 44b,” the internal terminal 44 located on the upper left side in FIG. 12 is referred to as “internal terminal 44c,” and the internal terminal 44 located on the upper right side in FIG. 12 is referred to as “internal terminal 44d.” Further, the internal terminals 44a, 44b, 44c, 44d are each referred to as “internal terminal 44” in the case in which the internal terminals 44a, 44b, 44c, 44d are not distinguished from each other.

The internal terminal 44a is disposed in the vicinity of the side surface electrode 46a. Similarly, the internal terminal 44b is disposed in the vicinity of the side surface electrode 46b, the internal terminal 44c is disposed in the vicinity of the side surface electrode 46c, and the internal terminal 44d is disposed in the vicinity of the side surface electrode 46d. Further, the internal terminals 44 are separated from each other, and the internal terminals 44 are disposed in the vicinities of the corners of the sidewall member 412 having a rectangular shape viewed from the γ-axis direction, respectively (see FIG. 9 and FIG. 12). Further, the internal terminals 44 and the side surface electrodes 46 correspond one-to-one to each other, and one side surface electrode 46 is electrically connected to one internal terminal 44.

It should be noted that the positions, the sizes, the shapes, and so on of the respective internal terminals 44 are not limited to those shown in the drawings. Further, the internal terminals 44 are all the same in size and shape in the illustration, but can also be different in size and shape from each other.

Each of such internal terminals 44 is only required to have conductivity, and can be configured by, for example, stacking coats of nickel, gold, silver, copper, or the like on a metalization layer (a foundation layer) of chromium or tungsten. Specifically, each of the internal terminals 44 can be formed of a metal film obtained by stacking covering layers including gold on the foundation layer including nickel or tungsten. Thus, it is possible to enhance the adhesiveness between the foundation layer and the sidewall member 412, and at the same time, it is possible to reduce or prevent oxidation of the internal terminals 44 to improve the durability.

### Conductive Connection Sections

As shown in FIG. 9 and FIG. 12, the plurality of (four in the present embodiment) conductive connection sections 45 electrically connects the internal terminals 44 and the side surface electrodes 46 to each other, respectively. It should be noted that in the following description, out of the four conductive connection sections 45, the conductive connection section 45 located on the lower left side in FIG. 12 is referred to as “conductive connection section 45a,” the conductive connection section 45 located on the lower right side in FIG. 12 is referred to as “conductive connection section 45b,” the conductive connection section 45 located on the upper left side in FIG. 12 is referred to as “conductive connection section 45c,” and the conductive connection section 45 located on the upper right side in FIG. 12 is referred to as “conductive connection section 45d.” Further, the conductive connection sections 45a, 45b, 45c, 45d are each referred to as “conductive connection section 45” in the case in which the conductive connection sections 45a, 45b, 45c, 45d are not distinguished from each other.

The conductive connection section 45a is bonded to the side surface electrode 46a and the internal terminal 44a to thereby electrically connect these constituents to each other. Similarly, the conductive connection section 45b is bonded to the side surface electrode 46b and the internal terminal 44b to thereby electrically connect these constituents to each other. The conductive connection section 45c is bonded to the side surface electrode 46c and the internal terminal 44c to thereby electrically connect these constituents to each other. The conductive connection section 45d is bonded to the side surface electrode 46d and the internal terminal 44d to thereby electrically connect these constituents to each other.

Further, as the constituent material of the conductive connection sections 45, there can be used, for example, gold, silver, and copper, and it is possible to use one of these materials alone, or two or more of these materials in combination. Further, specifically, the conductive connection sections 45 can be formed of, for example, Ag paste, Cu paste, Au paste or the like, but is preferably formed of in particular the Ag paste. The Ag paste is easy to obtain, and is superior in handling ability.

### External Terminals

As shown in FIG. 9 and FIG. 13, the plurality of (four in the present embodiment) external terminals 48 is disposed on the analog circuit board 61-side on the external surface of the sidewall member 412. These external terminals 48 are used for electrically connecting the analog circuit board 61 and the sensor device 4 to each other. It should be noted that in the following description, out of the four external terminals 48, the external terminal 48 located on the lower right side in FIG. 13 is referred to as “external terminal 48a,” the external terminal 48 located on the lower left side in FIG. 13 is referred to as “external terminal 48b,” the external terminal 48 located on the upper right side in FIG. 13 is referred to as “external terminal 48c,” and the external terminal 48 located on the upper left side in FIG. 13 is referred to as “external terminal 48d.” Further, the external terminals 48a, 48b, 48c, 48d are each referred to as “external terminal 48” in the case in which the external terminals 48a, 48b, 48c, 48d are not distinguished from each other.

The external terminals 48 are electrically connected to the corresponding internal terminals 44 via interconnections not shown provided to the sidewall member 412, respectively. Specifically, the external terminal 48a is electrically connected to the internal terminal 44a, the external terminal 48b is electrically connected to the internal terminal 44b, the external terminal 48c is electrically connected to the internal terminal 44c, and the external terminal 48d is electrically connected to the internal terminal 44d. Further, in the present embodiment, the external terminals 48 are disposed at positions corresponding to the internal terminals 44 described above, respectively. Specifically, at least a part of each of the external terminals 48 and at least a part of the internal terminal 44 corresponding to the external terminal 48 overlap each other viewed from the γ-axis direction (see FIG. 9, FIG. 12 and FIG. 13). Further, the external terminals 48 are separated from each other with a separation distance d1, and the external terminals 48 are disposed in the vicinities of the corners of the sidewall member 412 having a rectangular shape viewed from the γ-axis direction, respectively.

Further, as shown in FIG. 13, the separation distance d1 between the external terminal 48a and the external terminal 48b is longer than the width d2 (the length in the longitudinal direction of each of the external terminals 48a, 48b viewed from the front of the sheet in FIG. 13) of the external terminal 48a or the external terminal 48b. Similarly, the separation distance d1 between the external terminal 48c and the external terminal 48d is longer than the width d2 of the external terminal 48c or the external terminal 48d. It should be noted that the separation distance between the external terminal 48a and the external terminal 48c, and the separation distance between the external terminal 48b and the external terminal 48d are each longer than the separation distance d1.

Further, the external terminals 48 and the internal terminals 44 correspond one-to-one to each other, and one internal terminal 44 is electrically connected to one external terminal 48.

It should be noted that the positions, the sizes, the shapes, and so on of the respective external terminals 48 are not limited to those shown in the drawings. Further, the external terminals 48 are all the same in size and shape in the illustration, but can also be different in size and shape from each other. Further, the separation distance d1 between the external terminal 48a and the external terminal 48b and the separation distance d1 between the external terminal 48c and the external terminal 48d are equal to each other in the illustration, but can also be different from each other. Further, the external terminals 48 are all the same in width d2 in the present embodiment, but can also be different in width from each other.

Each of such external terminals 48 is only required to have conductivity, and can be configured by, for example, stacking coats of nickel, gold, silver, copper, or the like on a metalization layer (a foundation layer) of chromium or tungsten. For example, each of the external terminals 48 can be formed of a metal film obtained by stacking covering layers including gold on the foundation layer including nickel or tungsten. Thus, it is possible to enhance the adhesiveness between the foundation layer and the sidewall member 412, and at the same time, it is possible to reduce or prevent oxidation of the external terminals 48 to improve the durability.

Each of such external terminals 48 is disposed at a position corresponding to a terminal 613 provided to the analog circuit board 61 (see FIG. 9 and FIG. 14). It should be noted that FIG. 14 shows a connection section between the analog circuit board 61 and the sensor device 4 shown in FIG. 9 in an enlarged manner. As shown in FIG. 14, each of the external terminals 48 is connected to the terminal 613 provided to the analog circuit board 61 via a conductive bonding member 761 formed of, for example, solder.

Further, as shown in FIG. 14, in the present embodiment, there is adopted the configuration in which the thickness of the conductive bonding member 761 is thicker than each of the external terminal 48 and the terminal 613. Further, a solder resist 762 is disposed so as to surround the terminal 613. Further, the separation distance d4 between the solder resist 762 and the sidewall member 412 is larger than the thickness d3 of the solder resist 762. It should be noted that the solder resist 762 is used for reducing or preventing adhesion of the conductive bonding member 761 to the analog circuit board 61.

In such a manner, the sensor device 4 is connected to the analog circuit board 61. Thus, a signal output from the sensor device 4 is output to the analog circuit board 61.

The volume (external dimensions) of such a force detection device 1 as described hereinabove is not particularly limited, but is in a range of, for example, about 100 through 500 cm³.

The sensor device 4 is hereinabove described. Such a sensor device 4 has the force detection element 8. Further, as described above, the force detection element 8 (the stacked body) includes the piezoelectric element 81 as the “first piezoelectric element,” the piezoelectric element 82 as the “second piezoelectric element,” and the connection section 88 as the macromolecule polymer film located between the piezoelectric element 81 and the piezoelectric element 82.

According to such a sensor device 4, since the connection section 88 formed of the macromolecule polymer film is disposed between the piezoelectric element 81 and the piezoelectric element 82, it is possible to reduce the transmission loss of the external force between the piezoelectric element 81 and the piezoelectric element 82. Therefore, it is possible to reduce the degradation of the detection accuracy of the external force. Similarly, since the connection section 88 formed of the macromolecule polymer film is disposed between the piezoelectric elements 80 adjacent to each other, it is possible to reduce the loss of detection of the external force between the piezoelectric elements 80 adjacent to each other.

It should be noted that in the above description, the piezoelectric element 81 is taken as the “first piezoelectric element,” and the piezoelectric element 82 is taken as the “second piezoelectric element,” but it is sufficient to take one of the piezoelectric elements 80 adjacent to each other as the “first piezoelectric element,” and the other thereof as the “second piezoelectric element.” Therefore, it is also possible to take the piezoelectric element 82 as the “first piezoelectric element,” and the piezoelectric element 81 as the “second piezoelectric element,” or it is also possible to take the piezoelectric element 83 as the “first piezoelectric element,” and the piezoelectric element 84 as the “second piezoelectric element.”

Further, it is preferable that the connection section 88 formed of the macromolecule polymer film is disposed in every part between the piezoelectric elements 80 adjacent to each other as in the present embodiment. Thus, it is possible to effectively reduce the loss of detection of the external force, and thus, it is possible to accurately detect the external force. It should be noted that it is not required to dispose the connection section 88 formed of the macromolecule polymer film in every part between the piezoelectric elements 80 adjacent to each other, it is also possible to dispose the connection section 88 formed of the macromolecule polymer film in only the parts between the arbitrary piezoelectric elements 80 adjacent to each other.

Further, the piezoelectric element 81 (the first piezoelectric element) and the piezoelectric element 82 (the second piezoelectric element) each have the piezoelectric layer 801 for generating the charge Q due to the piezoelectric effect, and the output electrode layer 802 (electrode) provided to the piezoelectric layer 801, and for outputting the signal (the voltage V) corresponding to the charge Q. Further, similarly, the piezoelectric elements 83 through 86 each have the piezoelectric layer 801 and the output electrode layer 802 (the electrode). Further, the connection section 88 as the macromolecule polymer film is disposed between the output electrode layer 812 (the electrode) provided to the piezoelectric element 81 (the first piezoelectric element) and the output electrode layer 822 (the electrode) provided to the piezoelectric element 82 (the second piezoelectric element). Further, in the present embodiment, the connection section 88 as the macromolecule polymer film is disposed between the output electrode layers 802 (the electrodes) or between the ground electrode layers 803 provided to the piezoelectric layers 801 adjacent to each other. Thus, it is possible to reduce the occurrence of the transmission loss of the external force between the output electrode layers 802 and between the ground electrode layers 803, and thus, it is possible to reduce the degradation of the detection accuracy of the external force.

As described hereinabove, the force detection device 1 is provided with the first plate 211, the second plate 221, and the structure 20 located between the first plate 211 and the second plate 221. The structure 20 has the sensor devices each provided with at least one (six in the present embodiment) piezoelectric element 80, the first fixation sections 212 having contact with the respective sensor devices 4 and fixed to the first plate 211, and the second fixation sections 222 having contact with the respective sensor devices 4 and fixed to the second plate 221. Further, at least a part (the whole in the present embodiment) of the through hole 217 overlaps the structure 20 viewed from the direction in which the first plate 211 and the second plate 221 overlap each other.

According to such a force detection device 1, it is possible to transmit the external force to the sensor devices 4 via the first fixation sections 212 and the second fixation sections 222. Further, since at least apart of a portion (the female screw holes 214, the through holes 241 in the present embodiment) related to the connection between the attachment member 18 and the member 24, and the first plate 211 overlaps the structure 20 in a planar view, it is possible to reduce the transmission loss of the external force received by the end effector 17 to the sensor devices 4 compared to the case in which these constituents do not overlap each other. Therefore, it is possible to more accurately detect the external force.

Further, although in the present embodiment, the first plate 211 is a single tabular member, it is sufficient for the shape of the “first plate” to be provided with a part shaped like a plate having a plane for receiving the external force in at least a part of the “first plate.” By providing the plate-like shape having a plane to the part for receiving the external force, the external force can more accurately be captured. Further, the same applies to the “second plate.”

Further, as described above, the sensor devices 4 each have the force detection element 8 (the stacked body) having the plurality of piezoelectric elements 80 stacked on one another, and the stacking direction D1 of the plurality of piezoelectric elements 80 in the force detection element 8 crosses (at a right angle in the present embodiment) the normal line (the central axis A1) of the plate surface (the upper surface 215) of the first plate 211. Further, the stacking direction D1 is disposed along the plane direction of the x-y plane (see FIG. 5 and FIG. 9). Thus, it is possible to reduce the influence of the noise component due to the temperature variation from the signals output from the sensor devices 4, and thus, it is possible to more accurately detect the external force.

It should be noted that although in the present embodiment, the stacking direction D1 is perpendicular to the normal line of the upper surface 215, it is also possible for the stacking direction D1 to be tilted as much as a predetermined angle within a range larger than 0° and smaller than 90° with respect to the normal line of the upper surface 215. Further, it is also possible for the stacking direction D1 to be parallel to the upper surface 215.

Further, as described above, in the present embodiment, the force detection device 1 has the four sensor devices 4 (see FIG. 6). Further, the four sensor devices 4 are arranged in such a manner as shown in FIG. 6. Specifically, as described above, the four sensor devices 4 are arranged so that the + side of the γ axis is directed to the opposite side to the central axis A1 in a planar view, and the β-axis direction and the z-axis direction become parallel to each other. Thus, it is possible to calculate the translational force components Fx, Fy, Fz, and rotational force components Mx, My, Mz using only the charges Qα, Qβ without using the charge Qγ apt to be affected by the temperature variation. Therefore, the force detection device 1 is hard to be affected by the temperature variation, and is capable of performing high-accuracy detection. Therefore, it is possible to reduce or prevent the chance that, for example, the force detection device 1 is placed under the high-temperature environment, and the case 2 is thermally deformed, and the pressurization to the sensor devices 4 is changed from a predetermined value due to the thermal deformation to generate the noise component.

It should be noted that although the arrangement of the sensor devices 4 is not limited to the arrangement in the illustration, by arranging the four sensor devices 4 in such a manner as shown in FIG. 6, the six-axis components can be obtained with relatively simple arithmetic operations.

Further, although in the present embodiment, the number of the sensor devices 4 is four, but is not limited to four, and can also be, for example, one, two, three, five, or more. Further, although in the present embodiment, the force detection device 1 is the six-axis kinesthetic sensor capable of detecting the six-axis components, the force detection device 1 can also be a kinesthetic sensor for detecting one-axis component (e.g., a translational component in one-axis direction), two-axis components, three-axis components, four-axis components, or five-axis components. It should be noted that the force detection device 1 can detect the six-axis components, if the force detection device 1 is provided with four or more sensor devices capable of independently performing the detection along at least three axes (the α axis, the β axis, and the γ axis) perpendicular to each other.

Further, as described above, the sensor devices 4 each have the force detection element 8 (the stacked body) having the plurality of piezoelectric elements 80 stacked on one another, the plurality of side surface electrodes 46 disposed on the side surfaces 807, 808 of the force detection element 8, and the plurality of external terminals 48 (the connection terminals) provided to the package 40 (the sidewall member 412 in the present embodiment). Further, one side surface electrode 46 is electrically connected to one external terminal 48 (the connection terminal). Specifically, one side surface electrode 46 is electrically connected to one external terminal 48 (the connection terminal) via the internal terminal 44, the conductive connection section 45, and so on. Thus, since it is sufficient to prepare the external terminals 48 as much as the number of the side surface electrodes 46, the number of the external terminals 48 can be made relatively small. Therefore, as shown in, for example, FIG. 13, the separation distance d1 between the external terminals 48 can be made sufficiently long. Therefore, it is possible to reduce the possibility of the leakage between the external terminals 48 due to a foreign matter such as dirt. Further, since the separation distance d1 can be made sufficiently long, even in the case in which the conductive bonding member 761 includes a flux material, the cleaning performance of the flux material can be improved, and thus the residual of the flux material can also be reduced. It should be noted that the separation distance d1 denotes the distance between the external terminals 48 disposed closest to each other.

Further, in the present embodiment, the sensor devices 4 each have a plurality of internal terminals 44 provided to the package 40 (the sidewall member 412 in the present embodiment), and one side surface electrode 46 is electrically connected to one internal terminal 44. Therefore, since it is possible to reduce the number of the internal terminals 44 similarly to the external terminals 48, it is possible to make the distance between the internal terminals 44 sufficiently long as shown in FIG. 12. Therefore, it is possible to reduce the possibility of the leakage between the internal terminals 44 due to a foreign matter such as dirt.

Further, in the present embodiment, it is preferable for the separation distance d1 between the external terminals 48 (the connection terminals) to be larger than the width d2 of the external terminal 48 (the connection terminal). Thus, it is possible to make the separation distance d1 between the external terminals 48 sufficiently long, and it is possible to reduce the possibility of the leakage due to, for example, a foreign matter such as dirt. It should be noted that the width d2 denotes the length along the longitudinal direction of the external terminal 48 forming an elongated shape viewed from the γ-axis direction in the present embodiment.

Further, in the case in which the sensor devices 4 each have a plurality of external terminals 48 (the connection terminals) as in the present embodiment, it is preferable that all of the separation distances (including the separation distance d1) between the external terminals 48 are larger than the width d2 of the external terminals 48. Thus, the advantage described above can remarkably be exerted. It should be noted that it is also possible that at least one separation distance d1 is larger than the width d2 of an arbitrary external terminal 48.

Further, as described above, in the present embodiment, there is adopted the configuration in which the thickness of the conductive bonding member 761 is thicker than each of the external terminal 48 and the terminal 613 (see FIG. 14). Thus, it is possible to improve the cleaning performance of, for example, the foreign matter such as dirt and the flux material which can exist between the external terminals 48, and therefore, it is possible to reduce the possibility of the leakage.

### MODIFIED EXAMPLES

Then, some modified examples of the connection between the analog circuit board and the sensor device will be described.

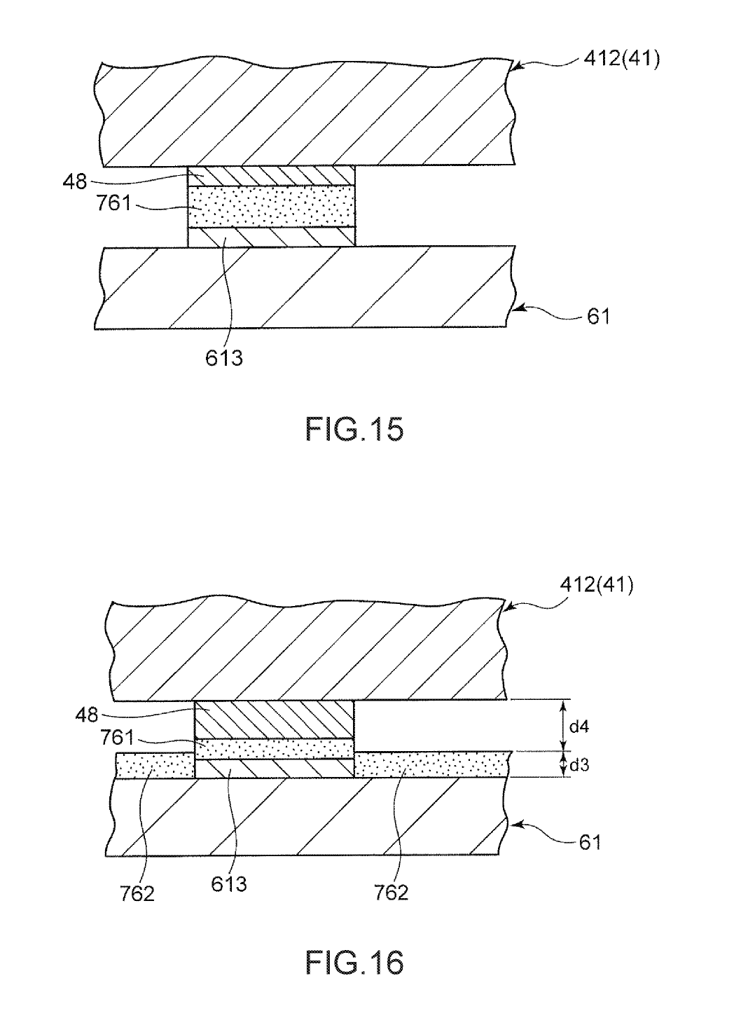

FIG. 15 is a diagram showing another example of the connection between the analog circuit board and the sensor device.

In FIG. 15, the solder resist 762 is removed. Here, since the separation distance d1 can be made sufficiently long by making the number of the external terminals 48 relatively small as described above, the cleaning performance between the external terminals 48 can be improved. Therefore, it is possible to reduce, for example, the residual dross of the flux material without providing the solder resist 762 as shown in FIG. 14.

FIG. 16 is a diagram showing another example of the connection between the analog circuit board and the sensor device.

The thickness of the external terminal 48 shown in FIG. 16 is thicker than the thickness of the terminal 613. Due to such an external terminal 48, it is also possible to easily make the separation distance d4 larger than the thickness d3. Thus, it is possible to improve the cleaning performance of, for example, the foreign matter such as dirt and the flux material which can exist between the external terminals 48, and therefore, it is possible to reduce the possibility of the leakage. It should be noted that it is also possible to exert substantially the same advantage by making the thickness of the terminal 613 thicker than the thickness of the external terminal 48.

The force detection device 1 is hereinabove described. As described above, the force detection device 1 is provided with the first plate 211, the second plate 221, and the sensor devices 4 disposed between the first plate 211 and the second plate 221. According to such a force detection device 1, it is possible to receive the external force by, for example, the end effector 17, and thus, transmit the force thus received by the first plate 211 and the second plate 221 to the sensor devices 4. Further, the force detection device 1 is provided with the sensor devices 4 described above. Therefore, according to the force detection device 1, it is possible to more accurately detect the external force.

### 3. Method of Manufacturing Connection Section of Force Detection Element

Then, a method of manufacturing the connection section 88 formed of the macromolecule polymer film including, for example, polysiloxane will be described.

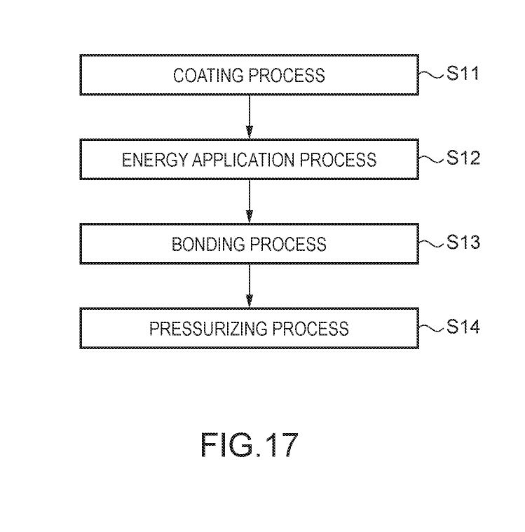

FIG. 17 is a flowchart of the method of manufacturing the connection section provided to the force detection element.

As shown in FIG. 17, the method of manufacturing the connection section 88 includes [1] a coating process (step S11), [2] an energy application process (step S12), [3] a bonding process (step S13), and [4] a pressurizing process (step S14). Hereinafter, each of the processes will sequentially be described. It should be noted that the description will hereinafter be presented taking a method of manufacturing the connection section 88 disposed between the piezoelectric element 81 and the piezoelectric element 82 as an example, but other connection sections 88 can also be manufactured using substantially the same method.

### [1] Coating Process (Step S11)

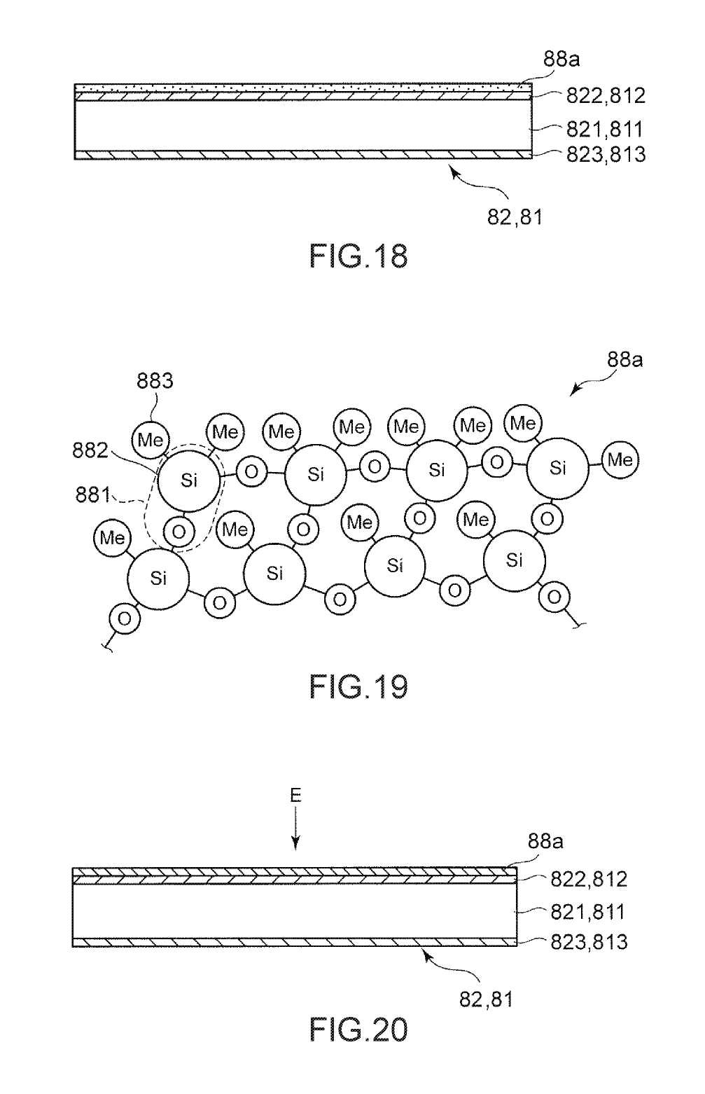

FIG. 18 is a diagram for explaining the coating process. FIG. 19 is a schematic diagram showing a part of a surface of the connection section in the coating process in an enlarged manner.

Firstly, as shown in FIG. 18, a material (e.g., octamethyltrisiloxane) including liquid polysiloxane as a base material of the connection section 88 is applied on the output electrode layer 812 of the piezoelectric element 81 and the output electrode layer 822 of the piezoelectric element 82 to form a coat 88a (a coating film). It should be noted that in FIG. 18 and FIG. 19 described later, the piezoelectric elements 81, 82 are collectively illustrated.

Further, the method of applying the material including polysiloxane is not particularly limited, and an inkjet method and a variety of coating methods can be used. Further, it is also possible for the material including polysiloxane to include a solvent, a dispersion medium, or the like.

As shown in FIG. 19, the surface of the coating film 88a has siloxane bond 881 and methyl groups 883 (organic groups) linked to the Si atom 882 in the siloxane bond 881.

It should be noted that the connection between the coating film 88a and the output electrode layers 812, 822 can be bonding based on physical binding, or can also be bonding based on chemical binding. For example, the surfaces of the output electrode layers 812, 822 can be covered with an oxide film, and in such a case, hydroxyl groups are linked (exposed) on the surface of the oxide film as a result. Therefore, the surface of the oxide film on the output electrode layers 812, 822 and the surface of the coating film 88a (the connection section 88) are connected with chemical conjugation. Thus, the bonding strength between the output electrode layers 812, 822 and the coating film 88a (the connection section 88) can be increased.

### [2] Energy Application Process (Step S12)

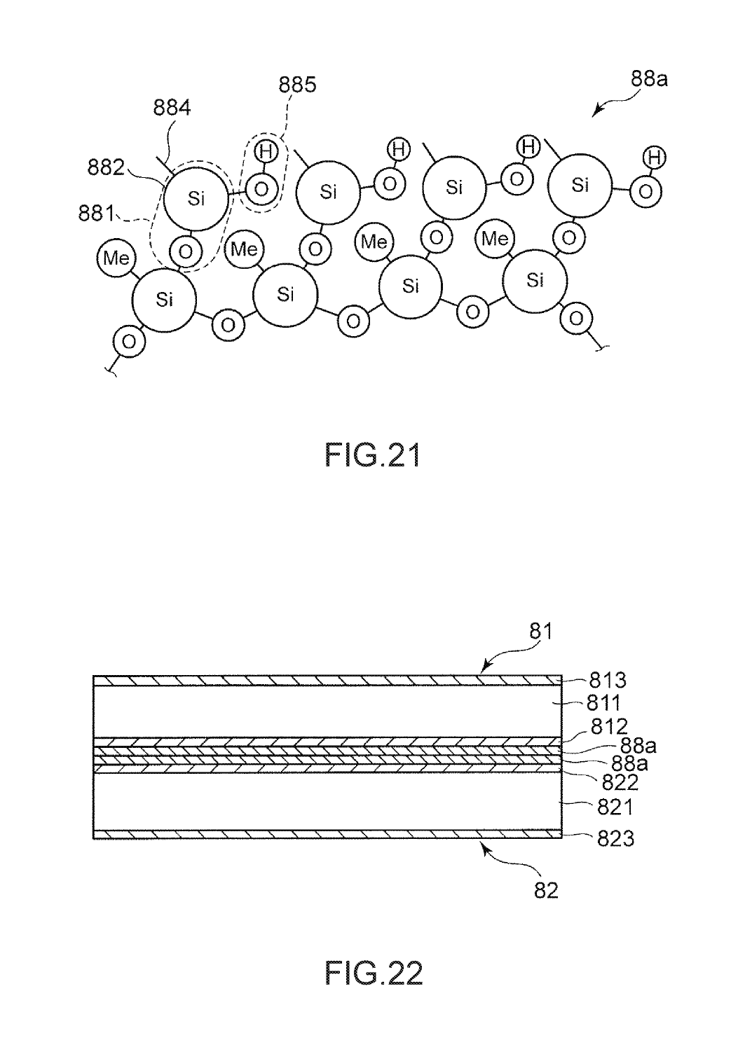

FIG. 20 is a diagram for explaining the energy application process. FIG. 21 is a schematic diagram showing a part of the surface of the connection section in the energy application process in an enlarged manner.

Then, as shown in FIG. 20, energy E is applied to the surface of the coating film 88a. Thus, a part of the molecular bond in the vicinity of the surface of the coating film 88a is broken, and the surface is activated.

As shown in FIG. 21, the state in which the surface is activated denotes the state in which apart of the molecular bond on the surface of the coating film 88a, specifically, for example, the methyl group 883, is broken, and dangling bond 884 (unbound bond) occurs, and in addition, the state in which the dangling bond is terminated by a polar group such as the hydroxyl group 885 (OH group).

As a method of applying the energy E, any method can be adopted, but there can be cited, for example, a method of irradiating with an energy beam such as an ultraviolet ray, a method of exposing to plasma (applying plasma energy), a method of heating the coating film 88a, and a method of exposing the coating film 88a to an ozone gas (applying chemical energy). Among these methods, the method of irradiating with an ultraviolet ray, or the method of exposing to the plasma is preferable. Thus, it is possible to promptly and appropriately activate a broad range on the surface of the coating film 88a while preventing the characteristics (e.g., mechanical characteristics, chemical characteristics) of the coating film 88a from deteriorating.

### [3] Bonding Process (Step S13)

FIG. 22 is a diagram for explaining the bonding process.

Then, as shown in FIG. 22, the two piezoelectric elements 81, 82 are bonded to each other so that the coating films 88a adhere to each other. Thus, the coating films 88a are chemically bonded to each other. In the present process, the dangling bonds 884 on the surfaces of the coating films 88a are bonded to each other although a specific illustration is omitted.

The connection between the coating films 88a is not achieved by bonding based on the physical binding such as an anchor effect as in, for example, an adhesive, but is achieved by bonding based on the firm chemical binding such as covalent binding. Therefore, the bonding between the coating films 88a is hard to be broken, and a bonding variation is also hard to occur. Further, the connection between the coating films 88a can be achieved at, for example, room temperature (e.g., about 25° C.) without performing a heat treatment, and is therefore simple and easy.

### [4] Pressurizing Process (Step S4)

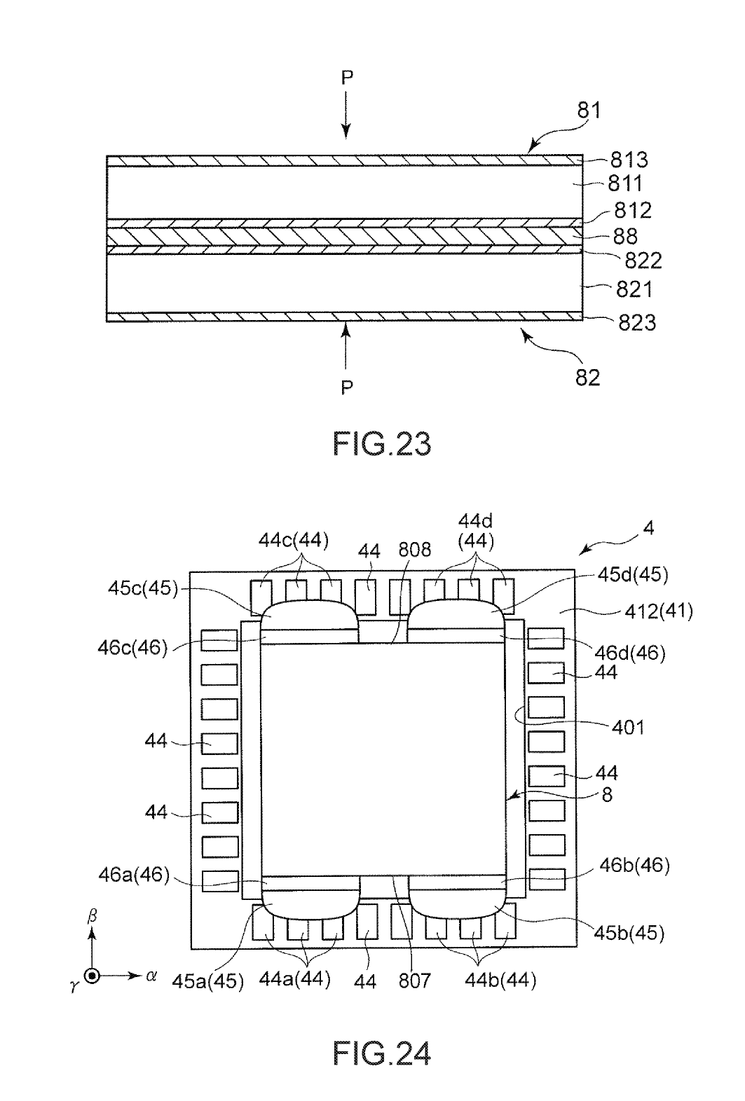

FIG. 23 is a diagram for explaining the pressurizing process.

Then, as shown in FIG. 23, pressure P is applied in a direction in which the two piezoelectric elements 81, 82 come closer to each other. The magnitude of the pressure P is not particularly limited, and is in a range of, for example, about 20 through 50 kN. The duration of applying the pressure P is not particularly limited, and is in a range of, for example, about 5 through 30 minutes.

Although specific illustration is not provided, by applying the pressure P, the dangling bonds 884 are bonded to each other, and dehydration condensation occurs between the hydroxyl groups 885, and thus the bonds to which the hydroxyl groups 885 have been bonded are bonded to each other on the interface between the coating films 88a and inside the coating films 88a. Such bonding occurs in a complicated manner so as to overlap (intertangle) each other to form the bond three-dimensionally. Thus, as shown in FIG. 23, the connection section 88 is formed with the two coating films 88a bonded to each other.

In such a manner as described hereinabove, it is possible to manufacture the connection section 88 provided to the force detection element 8. According to such a method as described above, the connection sections 88 can efficiently be manufactured. It should be noted that the method of manufacturing the connection section 88 described above is illustrative only. For example, it is also possible to make the connection sections 88 formed in advance intervene between the piezoelectric elements 80 to thereby manufacture the force detection element 8 having the piezoelectric elements 80 and the connection sections 88 alternately stacked on one another.

### Second Embodiment

Then, a second embodiment of the invention will be described.

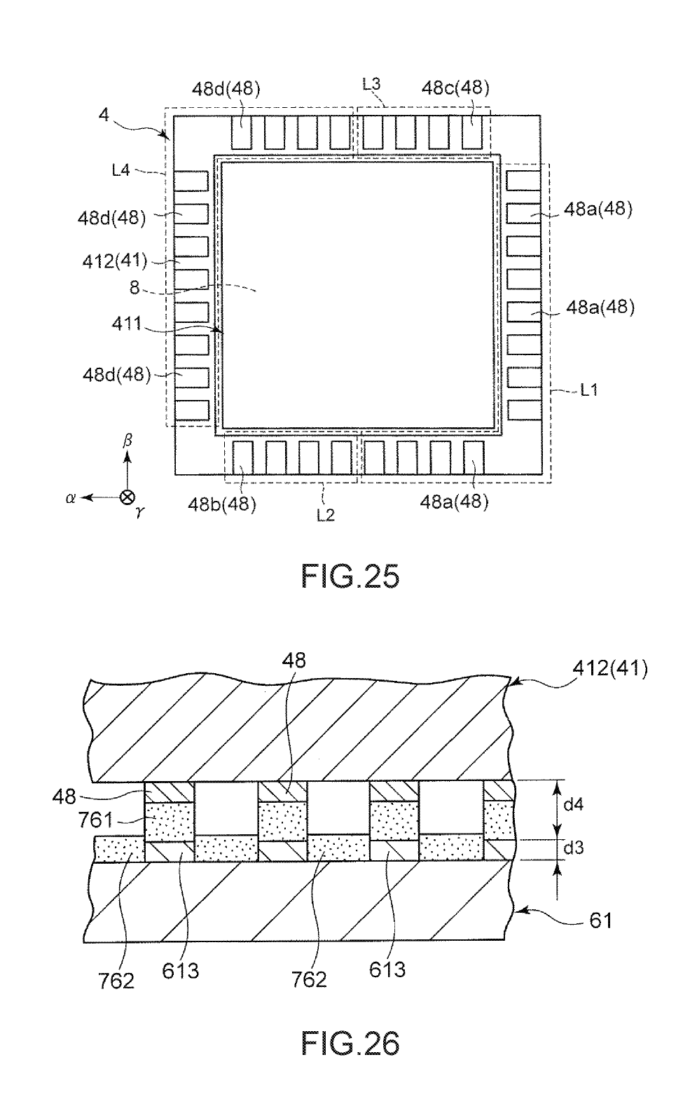

FIG. 24 is a plan view showing terminals disposed on a package provided to a sensor device according to the second embodiment. FIG. 25 is a plan view showing a back side of the package shown in FIG. 24. FIG. 26 is a diagram showing the connection between the analog circuit board and the sensor device.

The present embodiment is the same as the embodiment described above except the point that the configuration of the terminals provided to the package and the external terminals is different. It should be noted that in the following description, the second embodiment will be described with a focus on the difference from the embodiment described above, and the description of substantially the same issues will be omitted.

In the sensor device 4 shown in FIG. 24, one side surface electrode 46 is electrically connected to a plurality of (three in the present embodiment) internal terminals 44. The three internal terminals 44 electrically connected to the side surface electrode 46a each correspond to the internal terminal 44a, the three internal terminals 44 electrically connected to the side surface electrode 46b each correspond to the internal terminal 44b, the three internal terminals 44 electrically connected to the side surface electrode 46c each correspond to the internal terminal 44c, and the three internal terminals 44 electrically connected to the side surface electrode 46d each correspond to the internal terminal 44d. Further, in the present embodiment, there exist the internal terminals 44 not electrically connected to the side surface electrode 46.

Further, as shown in FIG. 25, in the sensor device 4, a plurality of external terminals 48 is electrically connected to a plurality of (three in the present embodiment) internal terminals 44. The external terminals 48 electrically connected to the internal terminals 44a each correspond to the external terminal 48a, the external terminals 48 electrically connected to the internal terminals 44b each correspond to the external terminal 48b, the external terminals 48 electrically connected to the internal terminals 44c each correspond to the external terminal 48c, and the external terminals 48 electrically connected to the internal terminals 44d each correspond to the external terminal 48d.

In the present embodiment, the external terminals 48 located on the right side and the lower right side (in the area surrounded by the dotted line L1) in FIG. 25 each correspond to the external terminal 48a. Further, the external terminals 48 located on the lower left side (in the area surrounded by the dotted line L2) in FIG. 25 each correspond to the external terminal 48b. Further, the external terminals 48 located on the upper right side (in the area surrounded by the dotted line L3) in FIG. 25 each correspond to the external terminal 48c. Further, the external terminals 48 located on the left side and the upper left side (in the area surrounded by the dotted line L4) in FIG. 25 each correspond to the external terminal 48d.

As described above, the sensor devices 4 in the present embodiment each have the force detection element 8 (the stacked body) having the plurality of piezoelectric elements 80 stacked on one another, the plurality of side surface electrodes 46 disposed on the side surfaces 807, 808 of the force detection element 8, and the plurality of external terminals 48 (the connection terminals) provided to the package (the sidewall member 412 in the present embodiment). Further, one side surface electrode 46 is electrically connected to a plurality of external terminals 48 (the connection terminals). Specifically, one side surface electrode 46 is electrically connected to the plurality of external terminals 48 (the connection terminals) via the internal terminals 44, the conductive connection sections 45, and so on. Therefore, even if some connections are broken, the output of the signal can be achieved with the remaining connections, and therefore, the output can stably be achieved.

Further, in the present embodiment, the sensor devices 4 each have the plurality of internal terminals 44 provided to the package 40 (the sidewall member 412 in the present embodiment), and one side surface electrode 46 is electrically connected to two or more of the internal terminals 44. Therefore, even if some connections are broken, the output of the signal can be achieved with the remaining connections, and therefore, the output can stably be achieved.

Further, in the present embodiment, the number of the external terminals 48a, 48d for outputting the charges Qα, Qβ used for the calculation of the external force is larger than the number of the external terminals 48b, 48c. Thus, even if some of the connections between the external terminals 48a, 48d and the terminals 613 of the analog circuit board 61 corresponding to these external terminals are broken, the output of the signal can surely be achieved with the remaining connections.

It should be noted that the number, the arrangement, and so on of the internal terminals 44 and the external terminals 48 are not limited to the number, the arrangement, and so on shown in the drawings. For example, the configuration in which one side surface electrode 46 is connected to one internal terminal 44, and the configuration in which one side surface electrode 46 is connected to two or more internal terminals 44 can exist in one sensor device 4. Further, for example, the configuration in which two or more internal terminals 44 are connected to two or more external terminals 48, and the configuration in which one internal terminal 44 is connected to one external terminal 48 can exist in one sensor device 4.

Further, as shown in FIG. 26, by, for example, making the thickness of the conductive bonding member 761 (e.g., solder) for connecting each of the external terminals 48 and corresponding one of the terminals 613 of the analog circuit board 61 to each other relatively thick, it is possible to easily make the separation distance d4 thicker than the thickness d3. Thus, even in the case in which the conductive bonding member 761 includes a flux material, the cleaning performance of the flux material can be improved, and thus the residual of the flux material can also be reduced.

According also to such a second embodiment as described hereinabove, substantially the same advantages as in the embodiment described above can be obtained.

### Third Embodiment

Then, a third embodiment of the invention will be described.

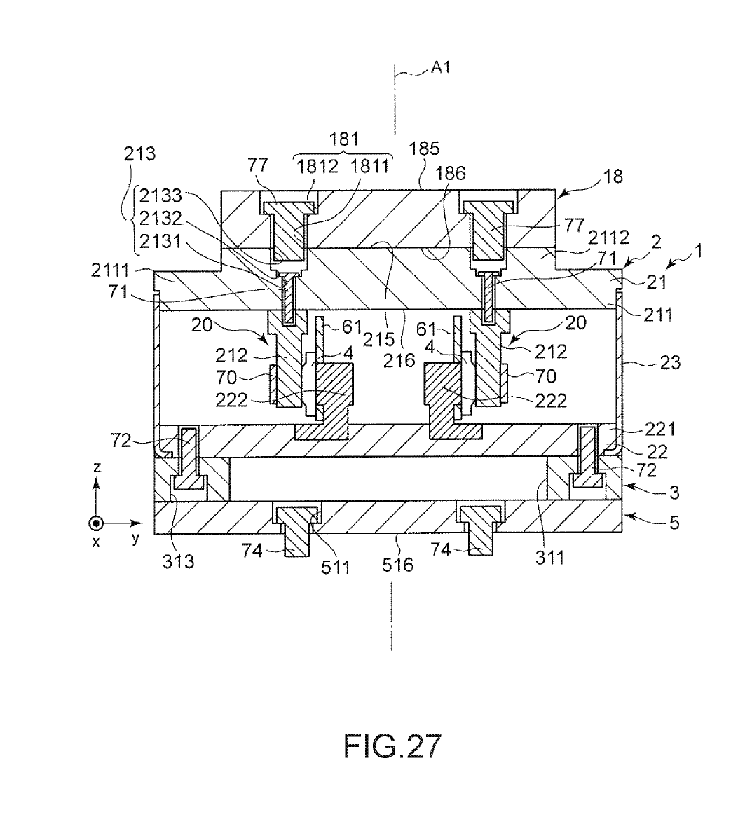

FIG. 27 is a cross-sectional view showing the connection between a force detection device and an attachment member in the third embodiment.

The present embodiment is substantially the same as the embodiments described above except mainly the point that the arrangement of the structure is different. It should be noted that in the following description, the third embodiment will be described with a focus on the difference from the embodiments described above, and the description of substantially the same issues will be omitted.

The plurality of structures 20 shown in FIG. 27 is located closer to the central axis A1 than the plurality of structures 20 shown in FIG. 8 in the first embodiment.

Further, in the present embodiment, there are provided through holes 213 formed in the central part 2112 of the first plate 211. As shown in FIG. 27, each of the through holes 213 has three holes 2131, 2312, 2133 different in opening area from each other. The hole 2131 opens in the lower surface 216. The hole 2132 is communicated with the hole 2131, and is larger in opening area than the hole 2131. The hole 2133 is communicated with the hole 2132, opens in the upper surface 215, and is larger in opening area than the hole 2132. Therefore, the hole 2133 constitutes an enlarged-diameter part with respect to the hole 2131, and the hole 2131 constitutes a reduced-diameter part with respect to the hole 2133.

Further, through the holes 2131, 2132, there is inserted a bolt 71 for connecting the first plate 211 and the first fixation section 212 to each other. The inner surface constituting the hole 2131 is provided with a female thread corresponding to the male thread of the bolt 71, and the head of the bolt 71 is fitted in a step formed between the hole 2131 and the hole 2132. The hole 2133 functions as a connection section for connecting the attachment member 18 and the first plate 211 to each other. Specifically, the hole 2133 is provided with a female thread corresponding to the male thread of the bolt 77 for connecting the attachment member 18 and the first plate 211 to each other. Further, through holes 181 of the attachment member 18 are disposed immediately above the respective through holes 213. It should be noted that in the present embodiment, the case 2 is not provided with the member 24.

According also to the force detection device 1 having such a configuration, it is possible to transmit the external force to the sensor devices 4 via the first fixation sections 212 and the second fixation sections 222. Further, since the structure 20 and the holes 2133 of the respective through holes 213 overlap each other in a planar view, it is possible to reduce the transmission loss of the external force having been received by the end effector 17 to the sensor devices 4 compared to the case in which these do not overlap each other. Therefore, it is possible to more accurately detect the external force. It should be noted that the connection sections for connecting the attachment member 18 and the first plate 211 to each other are not limited to the female threads, but can also be male threads, or can also be, for example, projections to be fitted.

According also to such a third embodiment as described hereinabove, substantially the same advantages as in the embodiments described above can be obtained.

### Fourth Embodiment

Then, a fourth embodiment of the invention will be described.

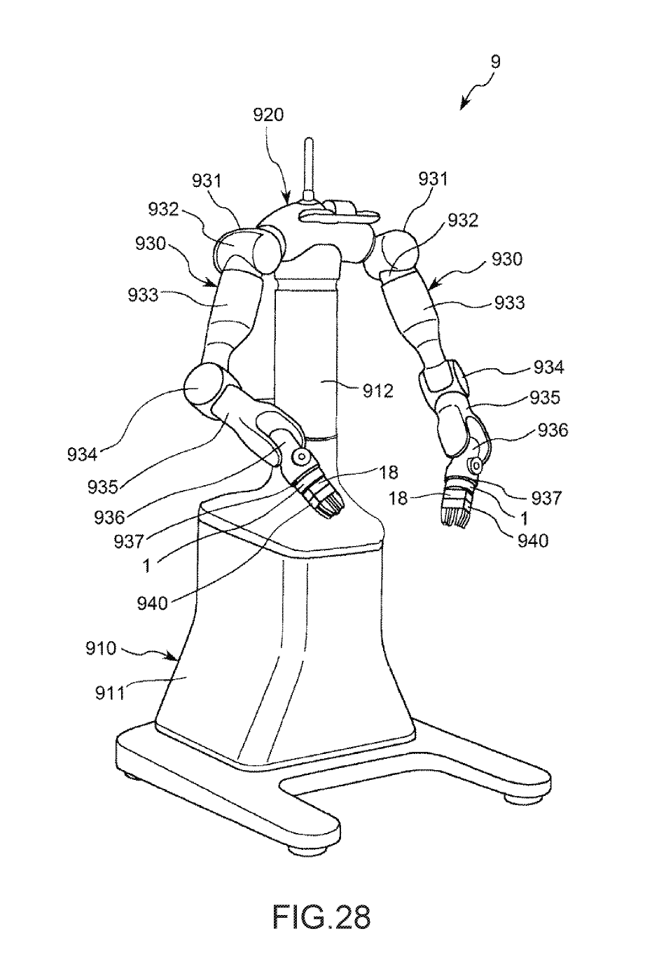

FIG. 28 is a perspective view showing a robot according to the fourth embodiment.

In the present embodiment, there is described an example of a robot different from the robot according to the first embodiment. It should be noted that as the force detection device provided to the present embodiment, there can be used the force detection device according to any one of the embodiments described above. In the following description, the fourth embodiment will be described with a focus on the difference from the embodiments described above, and the description of substantially the same issues will be omitted.

The robot 9 shown in FIG. 28 is a duplex arm robot, and has a pedestal 910, a body part 920 connected to the pedestal 910, and two robot arms 930 connected respectively to right and left sides of the body part 920. Further, to each of the robot arms 930, there is connected the force detection device 1, and to the force detection device 1, there is connected the end effector 940 (attachment target member) via the attachment member 18.

The pedestal 910 has a support section 911 to be fixed to the floor, the wall, the ceiling, a movable carriage, or the like, and a columnar section 912 connected to the support section 911. The body part 920 is connected to an upper part of the columnar section 912. Further, the pair of robot arms 930 are connected on both sides of the body part 920.

Each of the robot arms 930 has an arm 931 (a first arm), an arm 932 (a second arm), an arm 933 (a third arm), an arm 934 (a fourth arm), an arm 935 (a fifth arm), an arm 936 (a sixth arm), and an arm 937 (a seventh arm). These arms 931 through 937 are connected to one another in this order from the base end side toward the tip side. The arms 931 through 937 are made rotatable with respect to adjacent one of the arms 931 through 937 or the body part 920.

Further, the force detection device 1 is disposed between the arm 937 located in the tip part of each of the robot arms 930 and the end effector 940. The force detection device 1 is directly connected to the arm 937, and is connected to the end effector 940 via the attachment member 18.

According also to such a robot 9, since the force detection device 1 can be attached to the arm 937 (the robot arm 930), the external force applied to each of the end effectors 940 can be detected. Therefore, by performing the feedback control based on the external force detected by the force detection device 1, a more accurate operation can be performed.

It should be noted that although in the present embodiment, the force detection device 1 is provided to each of the two robot arms 930, it is also possible to provide the force detection device 1 to only either one of the two robot arms 930. In such a case, it is possible to control one of the robot arms 930 alone based on the information of the force detection device 1 provided to the one of the robot arms 930, or it is also possible to control the other of the robot arms 930 based on the information of the force detection device 1 provided to the one of the robot arms 930.

Further, the number of the robot arms 930 can be three or more, and in such a case, it is sufficient to connect the force detection device according to the present application example to at least one of the robot arms.

According also to such a fourth embodiment as described hereinabove, substantially the same advantages as in the embodiments described above can be obtained.

Although the sensor device, the force detection device, and the robot according to the invention are described hereinabove based on the embodiments shown in the accompanying drawings, the invention is not limited to these embodiments, but the configuration of each of the constituents can be replaced with those having an identical function and an arbitrary configuration. Further, it is also possible to add any other constituents to the invention. Further, it is also possible to arbitrarily combine any of the embodiments.

Further, the stacking direction of the piezoelectric elements is not limited to the configuration shown in the drawings. Further, the pressurization bolts can be provided as needed, and can also be omitted.

Further, although the sensor device is provided with the package in the above description, the sensor device is only required to be provided with at least one piezoelectric element, and is not required to be provided with the package. Further, the sensor device is not required to be provided with, for example, the lid member provided to the package. Further, the sensor device is not required to be provided with the seal member, and it is also possible for the base part and the lid member to directly be bonded to each other, or to be connected to each other with fitting or the like.

Further, besides the case in which the attachment target member is indirectly connected to the connection section via the attachment member, it is also possible to directly connect the attachment target member to the connection section.

Further, the robot according to the invention is not limited to the vertical articulated robot, but can have any configuration providing the configuration is provided with the arm and the force detection device according to the invention. For example, the robot according to the invention can be a horizontal articulated robot, or can also be a parallel link robot.

Further, the number of the arms provided to one robot arm of the robot according to the invention can be 1 through 5, or can also be 8 or more.

Further, the sensor device and the force detection device according to the invention can also be incorporated in equipment other than the robot, and can be mounted on a vehicle such as an automobile.

The entire disclosure of Japanese Patent Application No. 2017-071717, filed Mar. 31, 2017 is expressly incorporated by reference herein.

What is claimed is:

1. A sensor device comprising:
a stacked body including
a first piezoelectric element,
a second piezoelectric element, and
a macromolecule polymer film located between the first piezoelectric element and the second piezoelectric element.

2. The sensor device according to claim 1, wherein
the macromolecule polymer film includes polysiloxane.

3. The sensor device according to claim 1, wherein
the first piezoelectric element and the second piezoelectric element each have a piezoelectric layer adapted to generate a charge due to a piezoelectric effect, and an electrode provided to the piezoelectric layer and adapted to output a signal corresponding to the charge, and
the macromolecule polymer film is disposed between the electrode provided to the first piezoelectric element and the electrode provided to the second piezoelectric element.

4. The sensor device according to claim 3, further comprising:
a plurality of side surface electrodes disposed on a side surface of the stacked body,
wherein at least a part of a material constituting the side surface electrodes is same as at least apart of a material constituting the electrode.

5. The sensor device according to claim 4, wherein
the plurality of side surface electrodes includes a first layer including nickel, and a second layer including gold.

6. The sensor device according to claim 3, wherein
the piezoelectric layer includes quartz crystal.

7. The sensor device according to claim 3, wherein
defining thickness of the piezoelectric layer as T1, and thickness of the macromolecule polymer film as T2,
2. 0≤T1/T2≤10000 is fulfilled.

8. The sensor device according to claim 1, further comprising:
a package adapted to house the stacked body,
wherein the package includes
a base having a recess in which the stacked body is disposed,
a lid disposed so as to close the opening of the recess, and
a seal adapted to bond the base and the lid to each other.

9. The sensor device according to claim 8, wherein
the seal includes Kovar.

10. The sensor device according to claim 8, wherein
the base includes
a sensor plate, and
a side wall bonded to the sensor plate so as to form the recess together with the sensor plate, and
Young's modulus of the sensor plate is lower than Young's modulus of the side wall.

11. A force detection device comprising:
a first plate;
a second plate; and
a sensor device disposed between the first plate and the second plate, wherein
the sensor device includes
a stacked body including
a first piezoelectric element,
a second piezoelectric element, and
a macromolecule polymer film located between the first piezoelectric element and the second piezoelectric element.

12. The force detection device according to claim 11, wherein
the macromolecule polymer film includes polysiloxane.

13. The force detection device according to claim 11, wherein
the first piezoelectric element and the second piezoelectric element each have a piezoelectric layer adapted to generate a charge due to a piezoelectric effect, and an electrode provided to the piezoelectric layer and adapted to output a signal corresponding to the charge, and
the macromolecule polymer film is disposed between the electrode provided to the first piezoelectric element and the electrode provided to the second piezoelectric element.

14. The force detection device according to claim 13, further comprising:
a plurality of side surface electrodes disposed on a side surface of the stacked body,
wherein at least a part of a material constituting the side surface electrodes is same as at least apart of a material constituting the electrode.

15. The force detection device according to claim 14, wherein
the plurality of side surface electrodes includes a first layer including nickel, and a second layer including gold.

16. A robot comprising:
a pedestal;
an arm connected to the pedestal; and
a force detection device attached to the arm, wherein the force detection device includes:
a first plate;
a second plate; and
a sensor device disposed between the first plate and the second plate, and
the sensor device includes
a stacked body including
a first piezoelectric element,
a second piezoelectric element, and
a macromolecule polymer film located between the first piezoelectric element and the second piezoelectric element.

17. The robot according to claim 16, wherein
the macromolecule polymer film includes polysiloxane.

18. The robot according to claim 16, wherein
the first piezoelectric element and the second piezoelectric element each have a piezoelectric layer adapted to generate a charge due to a piezoelectric effect, and an electrode provided to the piezoelectric layer and adapted to output a signal corresponding to the charge, and
the macromolecule polymer film is disposed between the electrode provided to the first piezoelectric element and the electrode provided to the second piezoelectric element.

19. The robot according to claim 18, further comprising:
a plurality of side surface electrodes disposed on a side surface of the stacked body,
wherein at least a part of a material constituting the side surface electrodes is same as at least a part of a material constituting the electrode.

20. The robot according to claim 19, wherein
the plurality of side surface electrodes includes a first layer including nickel, and a second layer including gold.
